(19) United States
(12) Patent Application Publication
(10) Pub. No.: US 2026/0363120 A1
(43) Pub. Date: Nov. 12, 2026

(54) POLYMERIC PACKAGE SUBSTRATES AND METHODS OF FABRICATION

(71) Applicant: GEORGIA TECH RESEARCH CORPORATION, Atlanta, GA (US)

(72) Inventors: Pratik Nimbalkar, Atlanta, GA (US); Vijay Narasimha, Lakshmi KUMAR, Atlanta, GA (US)

(21) Appl. No.: 19/475,308

(22) PCT Filed: Apr. 15, 2024
(86) PCT No.: PCT/US2024/024654

§ 371 Date: Oct. 14, 2025

Related U.S. Application Data
(60) Provisional application No. 63/496,217, filed on Apr. 14, 2023.
(60) Provisional application No. 63/518,691, filed on Aug. 10, 2023.

(51) Int. Cl. H10W 70/67; H10W 70/05

(52) U.S. Cl. CPC H10W 70/688; H10W 70/05

(57) ABSTRACT

Exemplary methods, systems, and devices are disclosed for the spontaneous deposition of a vapor-phase monomer of parylene, which could occur at or near ambient temperature, onto a workpiece to form a parylene polymer layer or a build-up structure of layers in the workpiece for use in device or component fabrication, electronic manufacturing, encapsulation, and packaging, or integration packaged substrate, e.g., semiconductor devices, e.g., chiplets, via advanced multi-surface interconnects.

### RELATED APPLICATION

This application claims priority to, and the benefit of, U.S. Provisional Patent Application No. 63/496,217, filed Apr. 14, 2023, entitled “POLYMERIC PACKAGE SUBSTRATES AND METHODS OF FABRICATION,” and U.S. Provisional Patent Application No. 63/518,691, filed Aug. 10, 2023, entitled “EMBEDDED INTERCONNECT BRIDGE AND METHODS OF MAKING THE SAME,” which are incorporated by reference herein in their entireties.

### BACKGROUND

Semiconductor packages provide an enclosure for semiconductor devices (e.g., integrated circuits). Semiconductor packages both protect the semiconductor device and provide connections to the semiconductor device. Packages can include leads that couple the semiconductor device to various types of connectors and connections.

In some devices, a semiconductor package can include multiple semiconductor devices formed on a substrate. The semiconductor package can include connections formed on the substrate to couple the multiple semiconductor devices and/or connections formed on the substrate to connect the semiconductor devices to external devices.

There are benefits to the improvements of semiconductor package interfaces and methods of fabricating semiconductor packages among other electrical devices and components.

### SUMMARY

Exemplary methods, systems, and devices are disclosed for the spontaneous deposition of a vapor-phase monomer of parylene, which could occur at or near ambient temperature, onto a workpiece to form a parylene polymer layer or a build-up structure of layers in the workpiece for use in device or component fabrication, electronic manufacturing, encapsulation, and packaging, or integration semiconductor devices, e.g., chiplets, via advanced multi-surface, interconnects.

The exemplary spontaneous deposition of parylene can be employed to form a number of geometries to produce a finished electronic device with desirable electrical and mechanical properties, particularly with a low dielectric constant that is desirable for next-generation 5G, 6G, and millimeter-wave communication devices and components, photovoltaic cells, processors, GPU, AI chips, while being mechanically durable and chemically resistant to moisture. The spontaneous deposition via polymeric vapor can be performed, similar to chemical vapor deposition, but at a pressure at least 4 orders of magnitude lower than that of near vacuum operation typically employed for CVD and at or near ambient temperature, without any curing. With more relaxed manufacturing or fabrication environments (lower temperatures, no curing, less vacuum), the exemplary method and system can performed in a more straightforward operation and/or at a higher speed of fabrication.

Additionally, spontaneous polymerization of vapor-phase monomers directly onto the workpiece can eliminate the stresses due to curing and thermal expansion. This characteristic can be beneficially employed, particularly for larger panel-scale substrates and larger body-size interposers for advanced semiconductor packaging. The typical fabrication process for polymer often employs heating can cause the workpiece (e.g., semiconductor) to warp, thus limiting the size of the workpiece that can be employed with conventional processes. Larger semiconductor devices can be used in high-performance computing applications which can benefit from larger semiconductor sizes. The accumulated stresses due to multiple layers of polymer also cause cracking of brittle substrates such as glass and organic laminates. The use of low-stress polymer deposition processes such as parylenes can reduce these stresses significantly thereby preventing cracks and improving the reliability of substrates.

An example embodiment of the present disclosure includes polymeric package substrates and methods of fabrication for the polymeric package substrates. The example embodiments described herein can overcome the limitations of conventional polymer dielectrics. Those polymer dielectrics used in package substrates are often applied using vacuum lamination or liquid spin coating. These polymer dielectrics need to be cured as a part of the application process. This induces stresses in the substrate due to curing shrinkage associated with these dielectrics. These shrinkages occur due to the presence of solvent in these dielectrics. The curing stresses cause warping of the substrates, especially when the panel sizes or package/substrate sizes are considerably large. These conventional polymer dielectrics need to be cured before undergoing any further processing due to the inadequate mechanical stability of uncured dielectrics. The trend in semiconductor packaging is towards larger body/package/substrate sizes. Therefore, low-stress polymer dielectrics, as described in embodiments of the present disclosure, can overcome these issues by enabling large body/package/substrate sizes with minimum warpage. Larger substrates also have a problem of cracking during singulation or dicing. With the help of low-stress polymers like parylene, the stresses are significantly reduced since there is no curing shrinkage due to absence of solvents. These reduced stresses give improved reliability and prevent cracking of substrates during singulation and during operational use.

In some embodiments, the exemplary system and method can be employed for a molded substrate or other substrate described herein, e.g., with embedded chips for fan-out or embedded wafer bonding. Polymer dielectrics can be deposited on the molded substrate to form interconnections between multiple embedded/molded chips, chiplets (small, modular chips that can be combined to form a complete system-on-chip (SoC)), devices, components, passives, and/or actives.

An example embodiment of the present disclosure includes polymeric package substrates and methods of fabrication for the polymeric package substrates. The example embodiments described herein can overcome the limitations of conventional polymer dielectrics. Those polymer dielectrics used in package substrates are often applied using vacuum lamination or liquid spin coating. These polymer dielectrics need to be cured as a part of the application process. This induces stresses in the substrate due to curing shrinkage associated with these dielectrics. These shrinkages occur due to the presence of solvent in these dielectrics. The curing stresses cause warping of the substrates, especially when the panel sizes or package/substrate sizes are considerably large. These conventional polymer dielectrics need to be cured before undergoing any further processing due to the inadequate mechanical stability of uncured dielectrics. The trend in semiconductor packaging is towards larger body/package/substrate sizes. Therefore, low-stress polymer dielectrics (as described in embodiments of the present disclosure) can overcome these issues by enabling large body/package/substrate sizes with minimum warpage.

The example embodiment of the present disclosure includes polymer dielectrics such as parylenes that can be vapor deposited. The mechanism of deposition in such dielectrics can be different than the conventional dielectrics. For example, Parylene can be vapor deposited onto substrates with a process that resembles chemical vapor deposition (CVD). However, the process pressures are higher at 10-100 mTorr (e.g., 100 mTorr) compared to the conventional vapor deposition pressures of <10⁻⁵ Torr. Parylene deposition is not a line-of-sight deposition, meaning the gaseous monomer uniformly deposits on all surfaces it comes into contact with. This results in truly conformal and uniform coatings without porosity over large panel areas. Parylene deposition can include three main steps—(1) Vaporization, (2) Pyrolysis, and (3) Deposition. The first step is the vaporization of the solid dimer can be carried out at 80-200 °C (e.g., 150 °C). Pyrolysis of the vaporized dimer can be carried out in the pyrolysis chamber at 400 °C-800 °C (e.g., 680 °C). The cleavage of the methylene-methylene bonds occurs during pyrolysis, which can yield the stable monomer diradical-para-xylylene. The monomer vapor then enters the deposition chamber, which can be at room temperature. The deposition and polymerization of parylene occur spontaneously on the substrate.

Spontaneous polymerization on the substrate can reduce or eliminate the curing stresses associated with conventional polymer dielectrics. This can minimize the warpage of the substrates, thus allowing better process control during the subsequent processing steps. Low warpage is especially crucial for lithography. Significantly warped substrates cause sub-optimal focusing during lithography, leading to poor resolution of photoresists. The accumulated stresses due to multiple layers of cured polymer leads to cracking of the brittle substrate cores. Spontaneous polymerization eliminates the curing stresses thereby minimizing the accumulated stresses in a multilayer substrate.

Polymerization of these polymers can take place at ambient/room temperatures, thereby eliminating the thermal stresses. Furthermore, spontaneous polymerization also eliminates the curing step, which is often necessary with conventional polymer dielectrics for further processing.

Thermal processes are usually expensive due to the consumption of high power and long process durations. Curing processes can add high or significant costs to conventional package substrates due to the multiple curing steps required for each layer of dielectric. Spontaneous polymerization on substrates also eliminates multiple curing steps, thereby lowering the cost significantly. The core substrate can be organic laminate, glass, silicon, metal, polymer mold compound, fan-out, or a combination of one or more of those.

Vapor deposition of polymer dielectrics also allows deposition on both sides simultaneously, thus lowering the costs further. Furthermore, core substrates having through-holes can be coated with vapor-deposited polymer dielectrics due to their conformal coating characteristic.

Curing stresses can also cause the cracking of fragile substrate materials such as glass. Spontaneous polymerization also reduces the chances of such cracking due to zero curing stresses.

Such spontaneously deposited polymer dielectrics can be used in a package substrate for multiple layers having different functions, such as a build-up dielectric layer, solder-mask layer, thermal-interface material, underfill, and/or an overmold.

When used as a thermal-interface material, a thin conformal layer of the polymer dielectric can be deposited onto the package, followed by the deposition of a high thermal conductivity material such as a metal or a composite.

Parylenes also have other unique properties such as excellent barrier resistance to moistures, vapor and corrosive gases. Parylenes have low coefficient of friction and some of them are also biocompatible making them useful in variety of bio-compatible packaging applications. Low dielectric constant and low dielectric loss of Parylene-HT and Parylene-N is useful for high-frequency applications in semiconductors and electronic components.

Non-limiting examples of spontaneously deposited polymers that can be used in embodiments of the present disclosure include poly-para-xylylenes, which are widely known by their commercial names-Parylene-N, Parylene-C, Parylene-D, Parylene AF-4 atoms), Parylene SF, Parylene HT (AF-4, SCS product), Parylene A, Parylene AM (one methylene amine group per repeat unit), Parylene VT-4 (generic name, fluorine atoms on the aromatic ring), Parylene CF, and Parylene X (a cross-linkable version, not commercially available). Package substrates can utilize one or a combination of the above-mentioned polymers.

In an aspect, a method is disclosed of fabricating a package substrate, a semiconductor substrate, or a glass substrate, comprising: vaporizing a dielectric (from a liquid or solid) (e.g., having a dielectric constant less than 3, e.g., ultra-low k dielectric, or high k dielectric) at a first temperature (e.g., greater than vaporization temperature) and a first pressure (e.g., vaporization pressure) to form a vapor dimer of the dielectric; heating the vapor dimer in an inert environment to a second temperature (e.g., pyrolysis temperature) to form a vapor monomer at a second pressure (e.g., pyrolysis pressure), wherein the second temperature is higher than the first temperature, and wherein the second pressure is lower than the first pressure; and introducing the vapor monomer to a chamber having workpiece (e.g., glass or panel substrate, semiconductor device, or intermediate buildup of the workpiece) having an exposed surface to spontaneously deposit and polymerize the vapor monomer to form a layer (e.g., uniform and conformal layer) of a polymer on at least the exposed surface of the workpiece. The chamber may have a spontaneous polymerization environment at a third temperature lower than the second temperature and a third pressure lower than the third pressure.

In some embodiments, the spontaneous polymerization environment is at or near ambient temperature (e.g., 20-30 degrees Celsius). The spontaneous polymerization environment can be maintained at other temperatures, e.g., −50 to 200 degrees Celsius).

In some embodiments, the workpiece comprises a single-layer or multi-layer glass, a second polymer, metal, silicon, semiconductor material, or a combination thereof.

In some embodiments, the workpiece comprises a glass substrate or a second polymer substrate (e.g., panel).

In some embodiments, the polymer has a ratio of a total thickness of build-up layers to the thickness of the workpiece (e.g., core substrate) between 0.01 and 0.5.

In some embodiments, the workpiece comprises a first exposed surface and a second exposed surface opposite to the first exposed surface, and wherein the vapor monomer is spontaneously deposited and polymerized simultaneously on both the first exposed surface and the second exposed surface to form a layer (e.g., uniform and conformal layer) of the polymer on the first exposed surface and the second exposed surface.

In some embodiments, the method further includes introducing an additional vapor monomer to the chamber to spontaneously deposit and polymerize the additional vapor monomer to form an additional layer of the polymer on a portion of the workpiece.

In some embodiments, the method further includes successively introducing additional vapor monomer to the chamber to spontaneously deposit and polymerize each additional vapor monomer to form successive additional layers of the polymer on successive layers of the workpiece.

In some embodiments, the substrate comprises a package substrate having a core substrate with multiple layers of copper and polymer dielectric.

In some embodiments, the workpiece comprises a package substrate having a core substrate with multiple layers of (i) patterned copper comprising two metal layers and (ii) the polymer, wherein micro vias/blind vias are formed in the polymer (e.g., using laser drilling) for vertical connection of the two metal layers.

In some embodiments, the workpiece comprises one or more through-package-vias (TPVs), each of the TPVs is conformally coated with the polymer (e.g., filling the defects, voids, and cracks in the core substrate).

In some embodiments, the method further includes depositing a metal layer via electroless or sputtering following the forming of the layer of the polymer.

In some embodiments, the workpiece comprises a package substrate, the polymer forming a build-up dielectric layer, solder-mask layer, thermal-interface material, underfill, or an overmold.

In some embodiments, the method further includes depositing a thermally conductive material (e.g., metals, ceramics, compounds, and/or a composite) over the polymer, wherein the polymer provides a thin layer thermal interface having low thermal resistance to the thermally conductive material.

In some embodiments, the workpiece is manufactured using dual damascene, semi-additive, or embedded trench operations.

In some embodiments, the polymer comprises poly-para-xylylene (e.g., Parylene-HT, Parylene-N, Parylene-C, Parylene-D, Parylene AF-4, Parylene-SF, Parylene-A, Parylene-AM, Parylene VT-4, Parylene-CF, and Parylene-X), acrylic, epoxy, polyurethan, silicone, poly(tetrafluoroethylene), polyimide, fluoropolymer, or a combination thereof.

In some embodiments, the polymer has a dielectric constant of less than 3 (e.g., ultra low k dielectrics such as Parylene-HT, Parylene-N).

In some embodiments, the workpiece includes a layer of capacitors (e.g., high-density capacitors for power delivery) formed of two metal electrodes between a layer of the polymer (e.g., wherein the thickness of the polymer has a range of 1 nanometer to 10 micrometers, the polymer having a dielectric constant between 2 and 100.

In some embodiments, the polymer is deposited conformally to fill one or more open areas of the cavity (e.g., for embedded chips/chiplets, devices, components, passives, and/or actives components) to create an overburden; the overburden is removed by a subsequent planarization operation.

In some embodiments, the workpiece comprises a package substrate having a molded substrate with embedded chips (e.g., for fan-out or embedded wafer bonding), wherein the polymer is deposited on the molded substrate to form interconnections between multiple embedded/molded chips (e.g., chiplets, devices, components, passives and/or actives).

In some embodiments, the workpiece comprises an embedded bridge substrate comprising a carrier (e.g., a thin glass, thin silicon, thin metal, or thin inorganic carrier) with multiple layers of (i) metal and (ii) the polymer to form an interconnect (e.g., interconnection structure) (e.g., between chips/chiplets, devices, components, passives and/or actives).

In some embodiments, the embedded bridge substrate comprises a fused silica or glass carrier having a coefficient of thermal expansion from 0.1 ppm/K to 20 ppm/K.

In some embodiments, the workpiece has a length or width between 1 mm and 1000 mm (or more) (e.g., wherein the workpiece comprises a package substrate comprising heterogeneously integrated chips, chiplets, devices, components, passives, and/or actives).

In some embodiments, the workpiece comprises a package substrate comprising optical waveguides formed of the polymer (e.g., wherein the process of fabricating waveguides comprises polymer deposition and selective removal of polymer from specific areas using plasma and/or wet chemical etching).

In some embodiments, the workpiece comprises a package substrate comprising one or more filters, antennas, circulators, baluns, diplexers, power splitter & combiner, mixer, phase shifters, voltage-controlled oscillators, frequency multipliers and dividers, low noise amplifiers, power amplifiers, inductors, capacitors, co-planar waveguides, microstrip, waveguides, or combination thereof (e.g., for 5G and mm-wave wireless communication).

In some embodiments, the workpiece comprises a package substrate comprising the polymer conformally deposited onto one or more RF components, the method further comprising depositing a layer of conductive material (e.g., metal, high-k dielectric and/or a composite) for electromagnetic interference shielding.

In another aspect, an apparatus is disclosed comprising a package substrate comprising a core substrate configured with multiple layers of metal and polymer dielectric, wherein polymer layers of the polymer dielectric are deposited by spontaneous polymerization of a vapor monomer.

In some embodiments, the multiple layers of metal and polymer dielectric include micro vias or blind vias for vertical connection of at least two metal layers.

In some embodiments, the package substrate includes through-package-vias (TPVs), wherein the TPVs are conformally coated with the polymer dielectric by spontaneous polymerization, thereby filling defects, voids, and cracks in the core substrate.

In some embodiments, the multiple layers of metal are formed by metal deposition through electroless or sputtering followed by conformal dielectric coating via spontaneous polymerization.

In some embodiments, the multiple layers of metal and polymer dielectric comprise a build-up dielectric layer, a solder-mask layer, a thermal-interface material, an underfill, an overmold, or a combination formed by the spontaneous polymerization of the vapor monomer.

In some embodiments, the polymer dielectric is conformally deposited onto the packaged substrate, followed by a deposition of a thermally conductive material (e.g., metals, ceramics, compounds, and/or a composite).

In some embodiments, a layer of polymer dielectric acts as a thermal interface material, providing low thermal resistance.

In some embodiments, the package substrate is manufactured using a dual damascene, a semi-additive, or an embedded trench process.

In some embodiments, the polymer dielectric, as deposited, comprises poly-para-xylylenes (e.g., Parylene-HT, Parylene-N, Parylene-C, Parylene-D, Parylene AF-4, Parylene-SF, Parylene-A, Parylene-AM, Parylene VT-4, Parylene-CF, and Parylene-X), acrylic, epoxy, polyurethan, silicone, poly(tetrafluoroethylene), polyimides, fluoropolymers, or a combination thereof.

In some embodiments, the ratio of the total thickness of build-up layers to the thickness of the core substrate is 0.001 to 5.

In some embodiments, the package substrate comprises a layer of high-density capacitors (e.g., for power delivery), wherein the capacitor is formed of two metal electrodes with a layer of the polymer dielectric formed therebetween (e.g., wherein the thickness of the polymer dielectric has a range of 1 nanometers to 10 micrometers; the polymer dielectric having a high dielectric constant from 2 to 100).

In some embodiments, the polymer dielectric has a dielectric constant of less than 3.

In some embodiments, the package substrate comprises a cavity for embedded chips/chiplets, devices, components, passive components, active components, or a combination thereof, wherein polymer dielectric is deposited conformally to (i) fill open areas of the cavity and (ii) create an overburden followed by planarization to remove the overburden.

In some embodiments, the package substrate is a molded substrate with embedded chips for fan-out or embedded wafer bonding, wherein the polymer dielectric is deposited on the molded substrate to form interconnections between multiple embedded/molded chips, chiplets, devices, components, passive components, active components, or a combination thereof.

In another aspect, an embedded bridge substrate is disclosed comprising a carrier made of thin glass, silicon, metal, or inorganic material, the carrier formed of multiple layers of metal and polymer dielectric for forming interconnections between chips/chiplets, devices, components, passive components, active components, or a combination thereof, wherein polymer layers of the polymer dielectric are deposited by spontaneous polymerization of a vapor monomer.

In some embodiments, the polymer dielectric, as deposited, comprises poly-para-xylylenes (e.g., Parylene-HT, Parylene-N, Parylene-C, Parylene-D, Parylene AF-4, Parylene-SF, Parylene-A, Parylene-AM, Parylene VT-4, Parylene-CF, and Parylene-X), acrylic, epoxy, polyurethan, silicone, poly(tetrafluoroethylene), polyimides, fluoropolymers, or a combination thereof.

In some embodiments, the embedded bridge substrate includes fused silica or glass carrier having a coefficient of thermal expansion from 0.1 ppm/K to 20 ppm/K.

In some embodiments, the embedded bridge substrate has a rectangular size from 1 mm on a side to 1000 mm on a side.

In some embodiments, the embedded bridge substrate includes one or more optical waveguides made of the polymer dielectric, wherein the optical waveguides are fabricated by the spontaneous polymerization of the vapor monomer followed by a selective removal operation of polymer from specific areas using plasma and/or wet chemical etching.

In some embodiments, the embedded bridge substrate includes a combination of filters, antennas, circulators, baluns, diplexers, power splitter & combiner, mixers, phase shifters, voltage-controlled oscillators, frequency multipliers and dividers, low noise amplifiers, power amplifiers, inductors, capacitors, co-planar waveguides, microstrip, and waveguides for 5G and/or mm-wave wireless communication.

In some embodiments, the polymer dielectric is conformally deposited onto RF components, followed by a deposition of a thin layer of a conductive material, metal, high-k dielectric, a composite, or a combination thereof, for electromagnetic interference shielding.

### BRIEF DESCRIPTION OF THE DRAWINGS

The skilled person in the art will understand that the drawings described below are for illustration purposes only.

FIGS. 1A, 1B, 1C, and 1D each shows an example semi-additive process for device fabrication, according to an example embodiment of the present disclosure.

FIG. 2A illustrates an example deposition process of a polymer layer onto a workpiece during the fabrication of a device, e.g., as described in relation to FIGS. 1A-1D .

FIG. 2B shows the spontaneous polymerization process of parylene, or other polymers or material described herein, along with a representative image of the deposition equipment.

FIG. 2C shows the molecular structures of Parylene-N, Parylene-C, and Parylene-HT.

FIGS. 3A-3F each show example fabrication operations employing the spontaneous polymerization of a vapored monomer, e.g., as described in relation to FIGS. 1A-1D, in accordance with an illustrative embodiment.

FIGS. 4A-4F each shows an example device fabricated as a package substrate, a semiconductor substrate, and a glass substrate, respectively.

FIG. 5 shows microvia with a diameter drilled in thick Parylene-HT using UV laser.

FIGS. 6A-6E shows experimental results for a process for microvia formation in ULK dielectrics.

FIGS. 7A-7C show experimental results for polymer reliability.

FIGS. 8A-8B show experimental results for adhesion reliability.

FIG. 9 shows experimental results for a pre-sputtering process for enhanced adhesion.

FIGS. 10A and 10B show an example conventional semi-additive process flow, e.g., used in package substrates, using vacuum lamination or liquid spin coating and associated warpage issues.

### DETAILED SPECIFICATION

The details of one or more embodiments of the invention are set forth in the accompanying drawings and the description below. Other features, objects, and advantages of the invention will be apparent from the description and drawings and from the claims.

Throughout the description and claims of this specification, the word “comprise” and other forms of the word, such as “comprising” and “comprises,” means including but not limited to, and is not intended to exclude, for example, other additives, components, integers, or steps.

To facilitate an understanding of the principles and features of various embodiments of the present invention, they are explained hereinafter with reference to their implementation in illustrative embodiments.

Some references, which may include various patents, patent applications, and publications, are cited in a reference list and discussed in the disclosure provided herein. The citation and/or discussion of such references is provided merely to clarify the description of the disclosed technology and is not an admission that any such reference is “prior art” to any aspects of the disclosed technology described herein. In terms of notation, “[n]” corresponds to the nth reference in the list. For example, [1] refers to the first reference in the list. All references cited and discussed in this specification are incorporated herein by reference in their entireties and to the same extent as if each reference was individually incorporated by reference.

### Example Semi-Additive Process Flow for a Multilayer Package Substrate

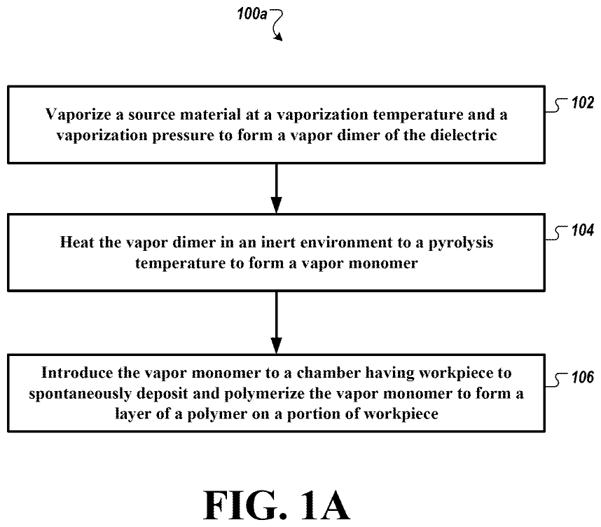

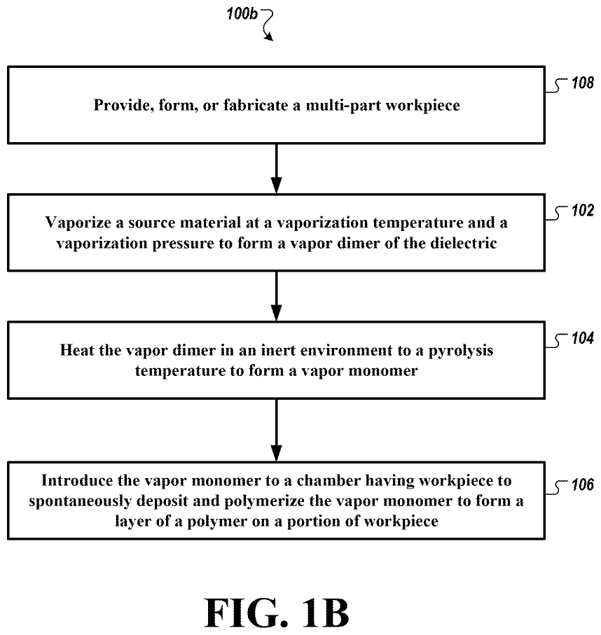

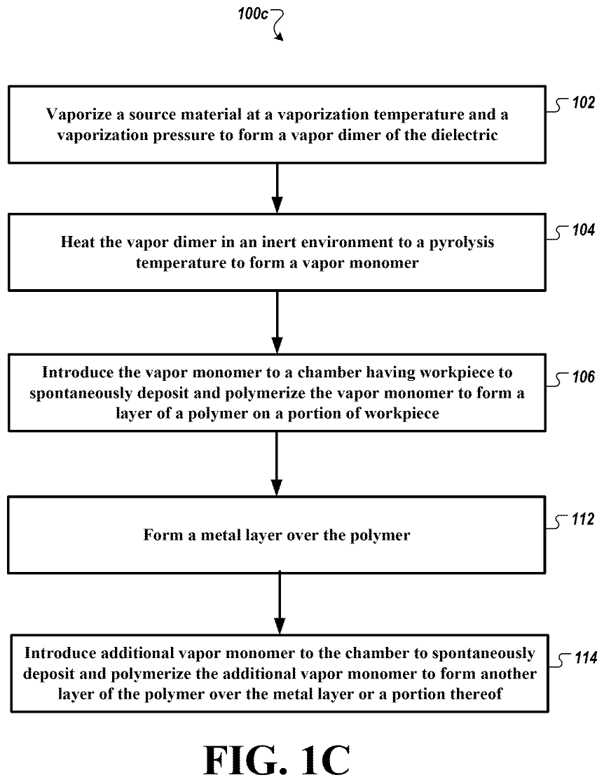

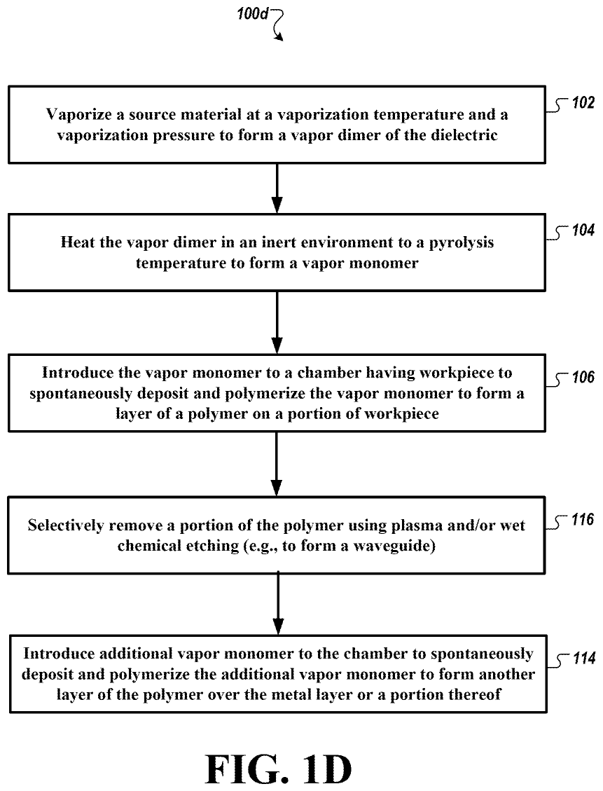

FIGS. 1A, 1B, 1C, and 1D each show an example semi-additive process 100 (shown as 100a, 100b, 100c, and 100d, respectively) for device fabrication, according to an example embodiment of the present disclosure. For Parylene, the process can include vapor deposited onto substrates with a process that resembles chemical vapor deposition (CVD).

However, the process pressures can be beneficially higher, e.g., 10-100 mTorr (e.g., 100 mTorr), compared to the conventional vapor deposition pressures of <10⁻⁵ Torr. The deposition can additionally not be line-of-sight deposition to allow the gaseous monomer to uniformly deposit on all surfaces it comes into contact with. This results in truly conformal and uniform coatings without porosity over large panel areas.

In the example shown in FIGS. 1A, 1B, 1C, and 1D, the process 100a, 100b, 100c, 100d each includes vaporizing (102) a source material at (i) a first temperature greater than vaporization temperature and (ii) a first pressure, e.g., vaporization pressure, to form a vapor dimer of the dielectric. The vaporization of the solid dimer, e.g., for parylene, can be carried out at 80-200 °C (e.g., 150 °C). In some embodiments, the vaporization temperature is around 80 °C, 90 °C, 100 °C, 110 °C, 120 °C, 130 °C, 140 °C, 150 °C, 160 °C, 170 °C, 180 °C, 190 °C, or 200 °C.

The dielectric may be a poly-para-xylylene, e.g., Parylene-HT, Parylene-N, Parylene-C, Parylene-D, Parylene AF-4, Parylene-SF, Parylene-A, Parylene-AM (one methylene amine group per repeat unit), Parylene VT-4 (generic name, fluorine atoms on the aromatic ring), Parylene-CF, and Parylene-X (a cross-linkable version, not commercially available).

In some embodiments, the dielectric is an acrylic, an epoxy, a polyurethan, a silicone, a poly(tetrafluoroethylene), a polyimide, a fluoropolymer, or a combination thereof. The dielectric may be vaporized from a liquid or solid. The dielectric may have a dielectric constant less than 3, e.g., ultra-low k dielectric, or it may have a high k dielectric, e.g., for use in a capacitor, e.g., from 3 to 50, e.g., about 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, or 50.

The vaporization temperature and pressure may vary based on the selected dielectric material, which may be chosen for attributes including a low dielectric constant, stability under semiconductor processing conditions, and compatibility with subsequent manufacturing steps of semiconductor devices.

Following vaporization, the process 100a (as well as 100b, 100c, 100d) then includes heating (104) the vapor dimer in an inert environment to a second temperature, e.g., at least or greater than the pyrolysis temperature, to form a vapor monomer at a second pressure, e.g., pyrolysis pressure. The second temperature is higher than the first temperature, and the second pressure is lower than the first pressure. This heating step occurs within a temperature range that ensures the complete transformation of the vapor dimer to a monomer, subject to the physical properties of the dimer and the ambient environment conditions. The inert environment prevents undesired chemical reactions during pyrolysis. Pyrolysis of the vaporized dimer of parylene can be carried out in a pyrolysis chamber at 400-800 °C (e.g., 680 °C). The cleavage of the methylene-methylene bonds occurs during pyrolysis, which can yield the stable monomer diradical-para-xylylene.

Following pyrolysis, the process 100a (as well as 100b, 100c, 100d) then includes introducing the vapor monomer to a chamber having workpiece having an exposed surface to spontaneously deposit and polymerize the vapor monomer to form a layer of a polymer of that monomer on at least the exposed surface of the workpiece, the chamber having a spontaneous polymerization environment at a third temperature lower than the second temperature and a third pressure lower than the third pressure. The heated monomer vapor can enter the deposition chamber, which can be at room or ambient temperature (e.g., at or near 25 °C). The deposition and polymerization of parylene occur spontaneously on the substrate to form a uniform and conformal layer.

Vapor deposition of polymer dielectrics may be performed to deposit on both sides simultaneously. Thus, the fabrication of devices can be further reduced with respect to cost and time. Furthermore, core substrates having through-holes can be coated with vapor-deposited polymer dielectrics due to their conformal coating characteristic.

Such spontaneously deposited polymer dielectrics can be used in a package substrate for multiple layers having different functions, such as a build-up dielectric layer, solder-mask layer, thermal-interface material, underfill, and/or an overmold. In some embodiments, the spontaneous polymerization can occur in a chamber having a temperature of −80-200 C, e.g., around −50 °C, −40 °C, −30 °C, −20 °C, −10 °C, 0 °C, 10 °C, 20 °C, 30 °C, 40 °C, 50 °C, 60 °C, 70 °C, 80 °C, 90 °C, 100 °C, 110 °C, 120 °C, 130 °C, 140 °C, 150 °C, 160 °C, 170 °C, 180 °C, 190 °C, or 200 °C. The spontaneous polymerization can occur in a chamber having a pressure between 10-100 mTorr (e.g., 100 mTorr), e.g., 10 mTorr, 20 mTorr, 30 mTorr, 40 mTorr, 50 mTorr, 60 mTorr, 70 mTorr, 80 mTorr, 90 mTorr, 100 mTorr. The pressure can be higher than 10⁻¹ Torr (e.g., between 10⁻¹ and 10⁻⁵ Torr, e.g., around 10⁻², 10⁻³, 10⁻⁴ Torr.

In some embodiments, additives may be present in the chamber to embed such additives in the polymer.

Spontaneous polymerization of vapor-phase monomers directly onto the workpiece can eliminate the stresses due to curing and thermal expansion associated with other polymer deposition techniques. For larger panel-scale substrates and larger body-size interposers for advanced semiconductor packaging, this can be beneficial in avoiding the warpage of the workpiece to allow for larger size substrates to be used. Low warpage is especially crucial for lithography. Significantly warped substrates cause sub-optimal focusing during lithography, leading to poor resolution of photoresists.

Spontaneous polymerization also reduces the chances of such cracking due to zero curing stresses. Curing stresses can also cause the cracking of fragile substrate materials such as glass. Thermal processes are also expensive due to high power consumption and long process durations. Curing processes can also add high or significant costs to package substrate fabrication due to the multiple curing steps required for each layer of dielectric. In eliminating multiple curing steps via spontaneous polymerization operation, the cost of fabrication can be reduced significantly.

The workpiece may be composed of any material pertinent to semiconductor device fabrication, including glass, metal, silicon, or previously deposited layers of the device. The chamber is maintained under conditions that support spontaneous polymerization, characterized by specific temperature and pressure settings suitable for the deposition process. The workpiece may include a semiconductor wafer, a glass panel, or a portion of a semiconductor device that necessitates a polymeric layer for purposes such as mechanical stability, electrical function, or as part of a thermal management system. In various embodiments, the polymer layer deposited may act as a dielectric layer, a barrier layer, or a structural layer in the fabricated semiconductor device. The workpiece may be a single solid substrate or a multi-part substrate. Workpieces may include a core substrate, e.g., made of organic laminate, glass, silicon, metal, polymer mold compound, fan-out, or a combination of one or more of those.

### Multi-Part Substrate

FIG. 1B additionally shows processing 100b of the multilayer fabrication described in FIG. 1A for a multi-part substrate. The fabrication operation of FIG. 1A can be employed for the fabrication of integration devices having embedded chips/chiplets, devices, components, passives, and/or actives. The polymer can be deposited conformally to encapsulate the embedded chips/chiplets, devices, components, passive components, and/or active components.

The process 100b may be employed to fabricate a package substrate comprising a combination of filters, antennas, circulators, baluns, diplexers, power splitter & combiner, mixer, phase shifters, voltage-controlled oscillators, frequency multipliers and dividers, low noise amplifiers, power amplifiers, inductors, capacitors, co-planar waveguides, microstrip, waveguides for 5G and mm-wave wireless communication.

### Multi-Layer Device

FIG. 1C additionally shows processing 100c of the multilayer fabrication by successively performing the operation described in FIG. 1A. Process 100c includes forming (112) a metal layer over the polymer. Process 100c then includes introducing (114) additional vapor monomer to the chamber to spontaneously deposit and polymerize the additional vapor monomer to form another layer of the polymer over the metal layer or a portion thereof.

Copper Tracing. To form the metal layer over the polymer, photoresists (PRs), e.g., dry-film photoresists, can be laminated onto the substrate. In some embodiments, a spin-coating process can be used for liquid photoresist. Electroplating can then be carried out to form the metal layers to which the additional layer of layer of the polymer can be deposited.

[999—to be filled in by attorney]

Example Devices. The multi-layer fabrication can be used to fabricate a package substrate with multiple polymer and metal layers where the polymer build-up layers are deposited on a substrate in such a way that the polymer polymerizes on the substrate during deposition.

In an example, a package substrate having a core substrate with multiple layers of copper and polymer dielectric may be deposited per the exemplary method. Microvias/blind vias may be formed in the polymer using laser drilling for the vertical connection of two metal layers.

In another example, a package substrate involving polymer dielectric deposited per the exemplary method may be deposited onto various RF components, followed by the deposition of a thin layer of a conductive material, metal, high-k dielectric, and/or a composite for electromagnetic interference shielding.

In yet another example, a package substrate may have a cavity for embedded chips/chiplets, devices, components, passives, and/or actives to which the polymer deposited per the exemplary method may be deposited conformally to fill the open areas of the cavity and create an overburden. The process may be followed by a planarization process to remove the overburden.

In yet another example, a package substrate may have a layer of high-density capacitors for power delivery. The capacitor can be made of two metal electrodes with a thin layer of polymer dielectric in between the electrodes. The thickness of the polymer dielectric may be in the range of 1 nanometers to 10 micrometers, e.g., about 1 nm, 5 nm, 10 nm, 20 nm, 30 nm, 40 nm, 50 nm, 60 nm, 70 nm, 80 nm, 90 nm, 100 nm, 200 nm, 300 nm, 400 nm, 500 nm, 600 nm, 700 nm, 800 nm, 900 nm, 1 μm. The polymer dielectric for capacitors maybe having a high dielectric constant from 2 to 100.

### Example Spontaneous Polymerization

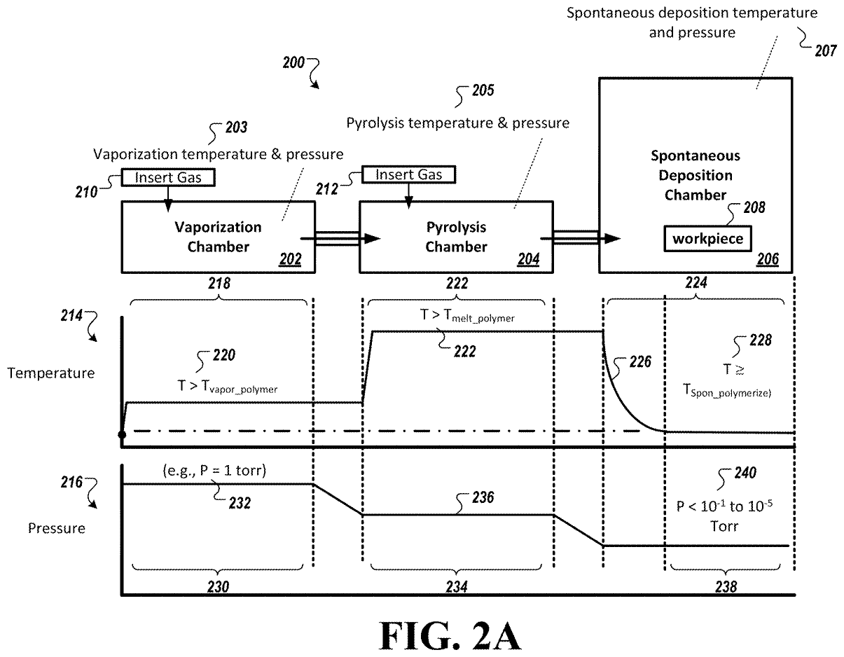

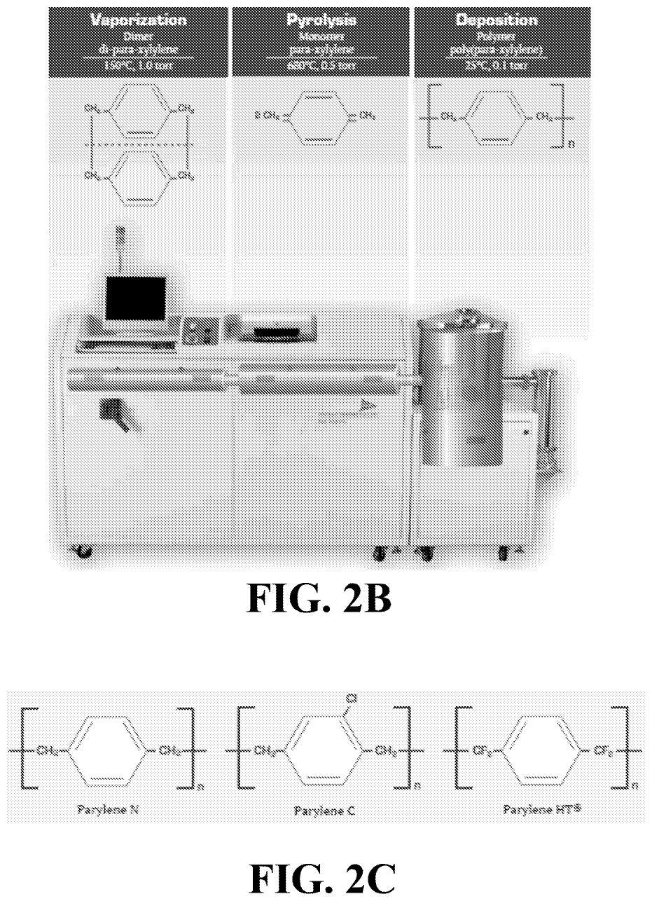

FIG. 2A illustrates an example deposition process 200 (e.g., of process 100a, 100b, 100c, or 100d) of a polymer layer onto a workpiece 208 during the fabrication of a device. In the example shown in FIG. 2A, the process 200 begins in the vaporization chamber 202 and converts a source material into a vapor dimer under specific vaporization temperature and pressure 203. The vaporization chamber 202 may be filled with an insert gas 210 (e.g., nitrogen). The vaporization parameters of chamber 202 may vary, as different polymers may require different temperatures and pressures for vaporization.

An example feedstock for parylene-C, as a source material, is “DPX-C” comprising principally 92% di-chlorinated molecules and 8% trichloro-and poly-chlorinated molecules.

Once the vapor dimer forms, it is transferred to a pyrolysis chamber 204 filled with an insert gas 212 (e.g., nitrogen), where it undergoes a transformation induced by temperature. The pyrolysis temperature and pressure 205 are controlled to ensure the breakdown of the vapor dimer into a vapor monomer, a process shown by the pyrolysis, which requires the vapor dimer to exceed melting temperature, T_{melt polymer}, of the polymer (shown as T>T_{melt_polymer}).

The vapored monomer is then introduced into the deposition chamber 206 having a spontaneous deposition temperature and pressure 207. The spontaneous deposition temperature is at or near ambient temperature (shown as T≥T_{ambient}). The vapored monomer can be introduced into the deposition chamber 206 while at or near the melting temperature. In the deposition chamber 206, the vapored monomer is cooled (226) to spontaneously polymerize as a polymer layer on the workpiece 208.

The evolution of temperature and pressure throughout the process is depicted through the temperature plot 214 and the pressure plot 216. The temperature must first surpass vaporization temperature 220 to vaporize a source dielectric (shown as T>T_{vapor_polymer}) and then elevate to or beyond the melting temperature (222) of the polymer (shown as T>T_{melt_polymer}) before decreasing to be at or near the spontaneous deposition temperature 228, ensuring that the deposition occurs under a condition conducive to spontaneous layer formation on the workpiece 206 in the spontaneous deposition chamber 208.

Pressure is modulated within the system. It begins within the vaporization chamber 202 at a pressure level (232) conducive to the vaporization of the polymer. As the process transitions into the pyrolysis chamber 204, pressure is decreased to an intermediate pressure 236 (optional) and eventually reaches a pressure 240 within the spontaneous deposition chamber 208, conducive for spontaneous deposition. This reduction to a pressure range of around 10⁻¹ Torr is crucial to ensure proper deposition and polymerization of the vapor monomer onto the workpiece 206. The pressure can be higher than 10⁻¹ Torr (e.g., between 10⁻¹ and 10⁻⁵ Torr, e.g., around 10⁻², 10⁻³, 10⁻⁴, which is an order or orders or magnitude less than conventional CVD).

Parylene Spontaneous Polymerization. The term “parylene,” as used herein, generally refers to a class of polymer having para-benzenediyl rings (—C₆H₄—) connected by 1,2-ethanediyl bridges (—CH₂—CH₂—). Parylene HT replaces the alpha hydrogen atom of the N dimer with fluorine. Parylene can be vapor deposited onto substrates with a process that resembles chemical vapor deposition (CVD). However, the process pressures are higher, being about 0.1 Torr, as compared to the conventional vapor deposition pressures of about than 10⁻⁵ Torr. Parylene deposition is not a line-of-sight deposition, meaning the gaseous monomer uniformly deposits on all surfaces it comes into contact with. This can result in truly conformal and uniform coatings without porosity over large panel areas. Parylene deposition consists of three main steps—(1) Vaporization, (2) Pyrolysis, and (3) Deposition.

Vaporization of the solid dimer of parylene can be carried out at ≈150 °C (e.g., 220). Pyrolysis of the vaporized dimer can be carried out in the pyrolysis chamber at 680 °C (e.g., 222). The cleavage of the methylene-methylene bonds occurs during pyrolysis to yield a stable monomer diradical-para-xylylene. The monomer vapor then enters the deposition chamber, e.g., maintained at or near ambient temperature (e.g., 25 °C). The deposition and polymerization of vapor parylene monomer occur spontaneously on the substrate (e.g., 208).

FIG. 2B shows the spontaneous polymerization process of parylene (or other polymers or material described herein), along with a representative image of the deposition equipment. Indeed, the process may be performed using commercially available semiconductor processing equipment, e.g., for chemical vapor deposition.

FIG. 2C shows the molecular structures of Parylene-N, Parylene-C, and Parylene-HT.

### Example Fabrication Steps

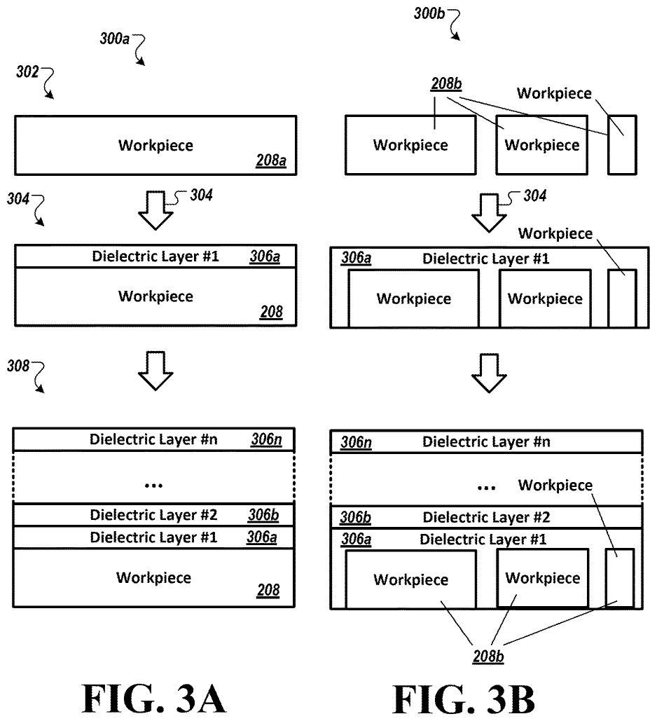

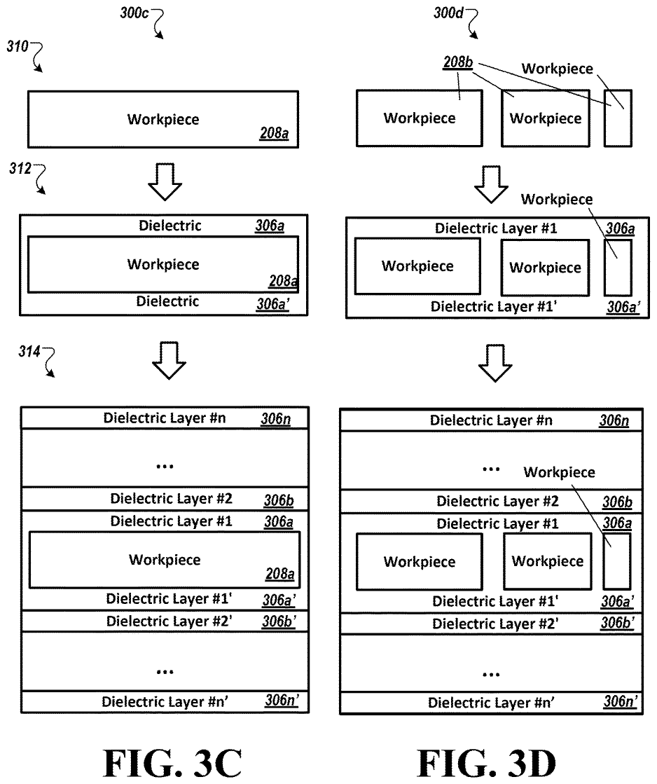

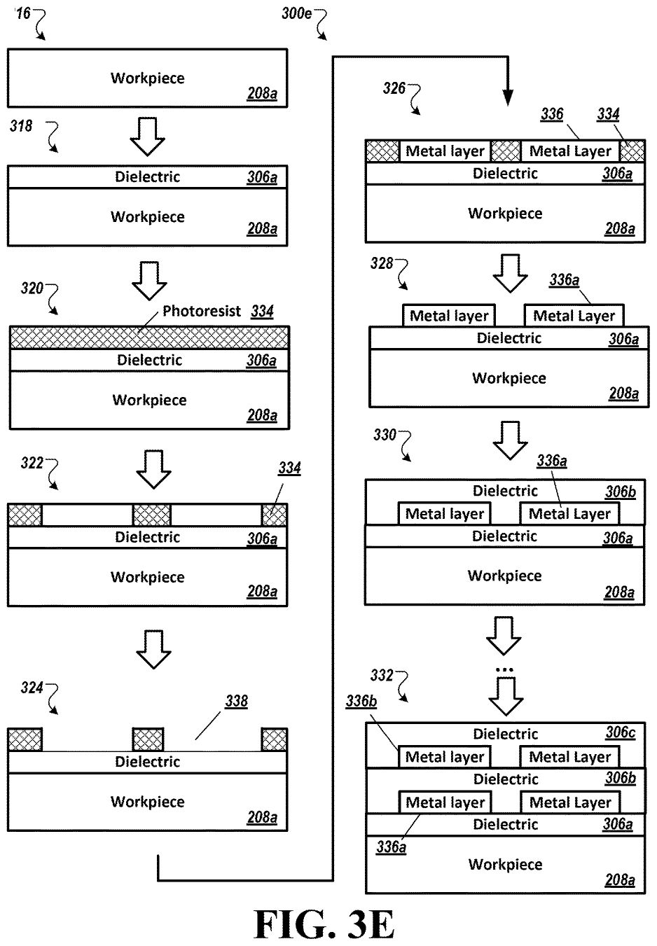

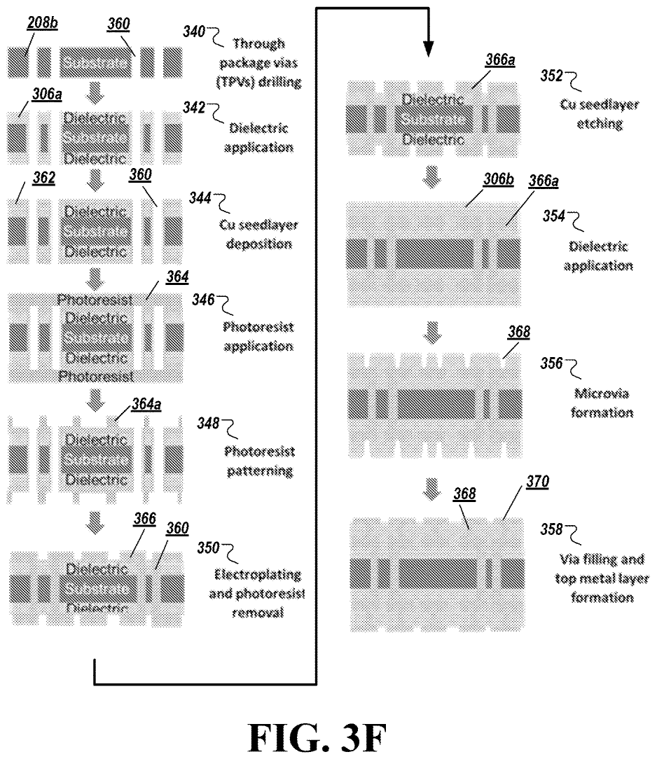

FIGS. 3A-3F each show example fabrication operations 300 (shown as 300a, 300b, 300c, 300d, 300e, 300f) involving the spontaneous polymerization of a vapored monomer as described in relation to FIGS. 1A-1D , in accordance with an illustrative embodiment.

In FIGS. 3A and 3B, operations 300a, 300b show an operation to form a single or multiple layers of polymer via spontaneous polymerization of a vapored monomer. In FIG. 3A, a workpiece 208 (shown as 208a) is provided (302) and is then deposited (304) with a layer of a polymer (e.g., parylene) (shown as “dielectric layer #1” 306a) per the method described in relation to FIG. 1A.

The process 300a may be successively repeated (308) to generate a build-up structure of multiple layers of the polymer (shown as “dielectric layer #1” 306a, “dielectric layer #2” 306b, to “dielectric layer #n” 306n), e.g., per the method described in relation to FIG. 1C.

In FIG. 3B, operation 300b shows multiple workpieces 208 (shown as 208b) being processed, e.g., per the method described in relation to FIG. 1B.

Double-sided fabrication. FIGS. 3C and 3D shows operations 300c, 300d to form on two sides of a workpiece a single or multiple layers of polymer via spontaneous polymerization of a vapored monomer. FIG. 3C shows the operation over a single workpiece. FIG. 3D shows the operation for a multi-part workpiece, e.g., as described in relation to FIG. 3B.

In FIG. 3C, a workpiece 208 (shown as 208a) is provided (310) that is maintained in a deposition chamber with exposed top and bottom surfaces. The workpiece 208a is then deposited (312) with a layer of a polymer (e.g., parylene) (shown as “dielectric layer #1” 306a and “dielectric layer #1′” 306a′) per the method described in relation to FIG. 1A. Because of the non-line-of-sight nature of the operation, a layer of the polymer is uniformly and conformally formed on both sides of the exposed surfaces.

Process 300c may be successively repeated (314) to generate a build-up structure of multiple layers of the polymer on both sides of the device (shown as “dielectric layer #1” 306a, “dielectric layer #2” 306b, to “dielectric layer #n” 306n and “dielectric layer #1′” 306a′, “dielectric layer #2′” 306b′, to “dielectric layer #n′” 306n′), e.g., per the method described in relation to FIG. 1C.

Metal Layer and Polymer Layer Fabrication. FIG. 3E shows operation 300e (via steps 316-332) to form a workpiece having a metal layer and a layer of polymer via spontaneous polymerization of a vapored monomer. In the example shown in FIG. 3E, a workpiece 208 (shown as 208a) is provided (316). The workpiece 208a is then deposited (318) with a layer of a polymer (e.g., parylene) (shown as “dielectric layer #1” 306a). A photoresist layer 334 (shown as 334) is then applied (320). The photoresist 334a can be patterned and removed (322). Electroplating can be performed (326) to deposit a metal pattern in a metal layer 336. The photoresist (334) is then removed (328) to provide an exposed metal layer 336 (shown as 336a). Subsequently, a second polymer layer 306b can be deposited over the metal layer 336a, to form the multi-layer structure. In some embodiments, a planarization operation is performed to treat the polymer layer 306b prior to further processing.

The process 300e may be successively repeated (332) to generate a build-up structure of multiple layers of the polymer (shown as 306a, 306b, 306c) and the metal layer (336a, 336b).

Further processing (not shown) may be performed, e.g., to form micro vias/blind vias, e.g., via laser drilling and subsequent metallization.

In some embodiments, the cavity (338) can be employed to embed chips/chiplets, devices, components, passives, and/or actives to which a polymer layer can be deposited per the exemplary method to fill the open areas of the cavity and create an overburden. The process may be followed by a planarization process to remove the overburden.

In some embodiments, the cavity (338) can be employed to form a layer of high-density capacitors. Two metal electrodes can then be formed with a layer of the polymer dielectric formed therebetween.

Metal Layer and Polymer Layer Fabrication with Inter-layer Vias and Through-Package Vias. FIG. 3F shows operation 300f (via steps 340-358) to form a workpiece 208 (shown as 208b) having a metal layer and a layer of polymer via spontaneous polymerization of a vapored monomer. In the example shown in FIG. 3F, a workpiece 208b is provided (340) having two sides exposed, e.g., as described in relation to FIG. 3D, the workpiece 308b having through-package-vias drilled 360 therein. The same operation can be performed for a single exposed surface, e.g., as described in relation to FIG. 3C.

In FIG. 3F, the workpiece 208b is then deposited (shown as “dielectric application” 342) with a layer of a polymer (e.g., parylene) (shown as 306a). A copper seed layer is deposited (344) to form a metal layer 362 over the polymer layer 306a and within the through-package-vias drilled 360. A photoresist layer 364 is then applied (346). The photoresist 364 (shown as 364a) is then patterned. The photoresist 364 is then removed, and electroplating is then performed (350) to deposit a metal pattern to form a metal layer 366 that connects to the through-package-vias drilled 360. The seed layer 344 (not shown) is then removed (352), e.g., via etching. Subsequently, a second polymer layer 306b is then deposited over the metal layer 336a to form the multi-layer structure. The second polymer layer 306b is then drilled to form (356) microvias (368). The vias (368) are filled, and an additional metal layer (370) is formed (358), e.g., via a metallization operation.

Indeed, the process (e.g., 34-356) may be successively repeated to fabricate multiple layers of the metal layers and dielectric layers.

In some embodiments, the cavity (338) can be employed to embed chips/chiplets, devices, components, passives, and/or actives to which a polymer layer can be deposited per the exemplary method to fill the open areas of the cavity and create an overburden. The process may be followed by a planarization process to remove the overburden.

Additional examples of processing, in addition to those described or referenced herein, that may be performed on the polymer layer 306 is provided in U.S. Patent Publication No. US20230215762A1, which is incorporated by reference herein in its entirety.

### Example Devices

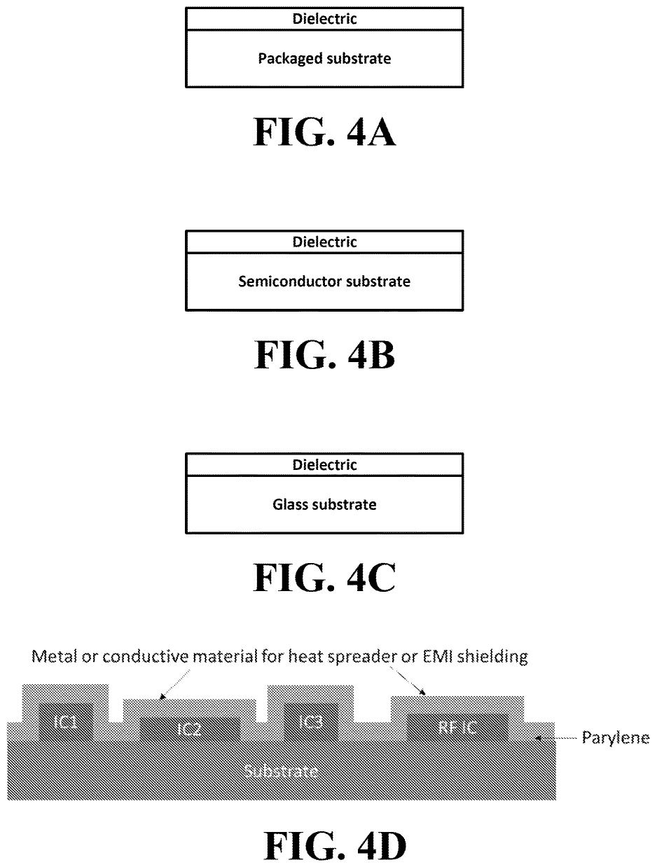

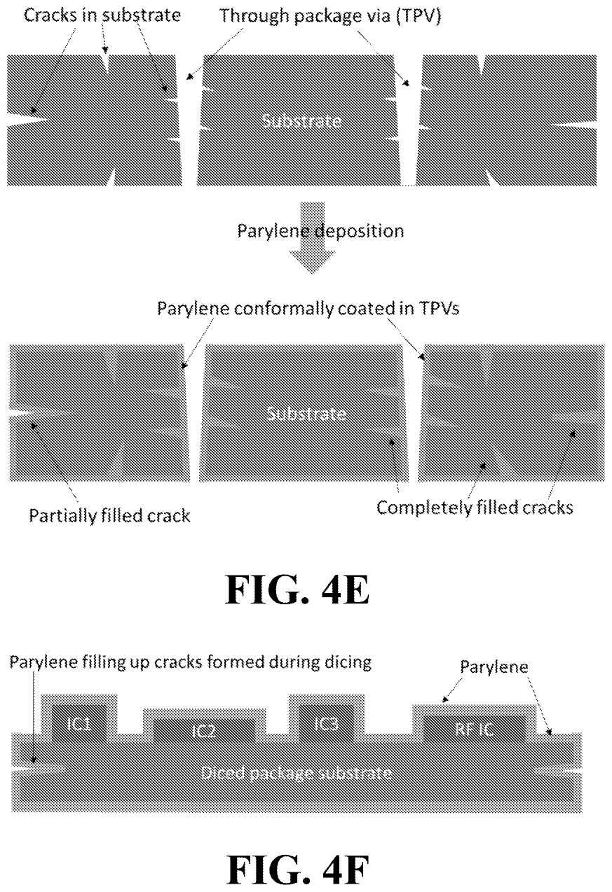

FIGS. 4A-4F each shows an example device fabricated as a package substrate, a semiconductor substrate, and a glass substrate, respectively.

Package substrate can be used for the core semiconductors of mobile devices and PCs. The package substrate can transmit electric signals between semiconductors and the main board, and protects semiconductors from external stress. Compared with general substrates, as th package substrate is a high-density circuit substrate containing more microcircuits, the assembly defects and incurred costs in directly bonding expensive semiconductors to the substrate can be reduced.

Semiconductor substrate (e.g., Si), also known as a wafer, is a solid substance that serves as the foundation for microelectronic devices. The substrate is the base material upon which epitaxial layers are deposited to form structures, which then undergo microfabrication processes to produce the end product.

Glass substrate (e.g., SiO₂) can handle higher temperatures more effectively while efficiently managing heat dissipation in high-performance chips, leading to superior thermal and mechanical stability for chips. Glass substrates can be employed for higher interconnect density.

The dielectric layer may be used to attach a metal layer for heat spreading, EMI shielding, or via interconnects (FIG. 4D).

FIG. 4E shows the dielectric layer may be used to encapsulate a substrate while also filling in cracks. FIG. 4F shows the dielectric layer encapsulating a diced package substrate having ICs mounted thereon while filling up cracks during a dicing operation.

RF devices. The exemplary system and method can be employed to integrate and/or fabricate package substrate other others described herein, e.g., as described in relation to FIG. 4A-4D , that can include any combination of filters, antennas, circulators, baluns, diplexers, power splitter & combiner, mixer, phase shifters, voltage-controlled oscillators, frequency multipliers and dividers, low noise amplifiers, power amplifiers, inductors, capacitors, co-planar waveguides, microstrip, waveguides for 5G and mm-wave wireless communication.

Waveguide and optical electronics. In some embodiments of the present disclosure, the package substrate or others described herein, e.g., as described in relation to FIG. 4A-4D , can include optical waveguides made of polymer dielectrics described herein. The process of fabricating waveguides can optionally include polymer deposition and selective removal of polymer from specific areas using plasma and/or wet chemical etching.

### Experimental Results and Additional Examples

A study was conducted to develop package redistribution layers (RDL) using the exemplary methods and systems described herein. RDL can interconnect various system components such as logic, memory, and passive components as components of an electronic package. The study focused on increasing the IO density and improvements in electrical performance. Increasing RDL IO density translates to scaling down RDL linewidth and spacing. Whereas, electrical performance improvement translates to minimizing electrical losses and reducing crosstalk. For reducing parasitic losses and crosstalk, lowering RDL capacitance is beneficial. Traditional silicon back-end RDL uses silicon dioxide as a dielectric which has a relatively high dielectric constant (Dₖ=4) and thus has fundamental limitations to improving electrical performance.

Among other things, the study designed and fabricated low R&C RDL and simulated the performance of Parylene-HT against SiO₂ dielectric. Materials, processes, and tools used for achieving 1.4/0.6 μmL/S with 3.3 μm height were described. A process was demonstrated for the formation of 1.6 μm diameter vias in Parylene-HT with 0.25 μm alignment tolerance leading up to a two-layer RDL structure.

The study also developed an example copper etching process, among other processes, that may be employed with the exemplary system and method.

Example materials, processes and tools for 1×3 micrometer copper traces. The study evaluated the use of dry-film photoresists. Dry-film photoresists (PRs) can be used in package substrate manufacturing as they can be laminated onto the substrate as compared to the more difficult spin-coating process used for liquids. Currently, photoresists used in packaging are negative-tone mainly due to their lower costs, which may have challenges with adhesion to seed-layer Cu, low resolution, larger thickness, and difficulty in stripping, among others. These challenges can be greater for finer RDL patterning at 1 μm/S. Because of fine line dimensions, the adhesion of PR to Cu can be important. Poor adhesion can lead to delamination and poor yields after development.

Negative-tone PRs often have poor resolution and are available in larger thicknesses>5 μm, which can be a challenge to fine-line patterning as a larger Depth-offocus (DoF) may be necessary to resolve 1 μm/S. Negative tone PRs can get cross-linked when exposed to UV radiation. The unexposed regions may dissolve during development to form the RDL pattern. Cross-linked PR can be hard to strip and thus leads to residues that cause short defects in RDL. Positive tone photoresists can provide higher resolution to provide higher yield, e.g., due to fewer defects, and they can be readily stripped because they do not undergo crosslinking reactions during processing. Generally, the chemically amplified photoresist can include a hydrophobic polymer with a protecting group and a photo-acid generator (PAG). The PAG molecule generates acid during the UV exposure process, and acid works as a catalyst for the deprotection reaction during the post-exposure bake. The polymer in the exposed area changes from hydrophobic to hydrophilic completely and is dissolved in the developer solution. As a result, a positive-tone photoresist may enable better resolution than a negative-tone photoresist. The sensitivity of positive photoresist can be controlled by controlling photo-acid generation, enabling high aspect ratio structures while maintaining low exposure doses. In this example, the aspect ratio of RDL is defined as the ratio of the Cu/PR height to the half-line-pitch.

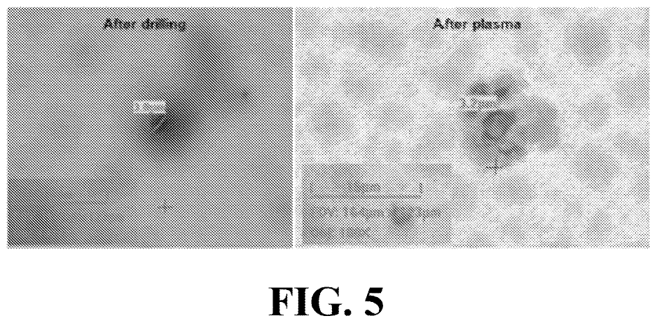

The study employed a positive-tone photoresist. Dose values were varied from 90 to 110 mJ/cm². FIG. 5A shows the optical images after plating and PR stripping. In the example implementation, the optimal dose value was found to be close to 100 mJ/cm². 1 μm/S resolved at 95-105 mJ/cm² dose values. Though 1 μm/S seems resolved even at 95 mJ/cm² the traces did not get plated, denoting incomplete PR opening. While at 110 mJ/cm² the lines are visibly over-exposed. Plasma descum was carried out using O₂ gas for making the PR surface hydrophilic and to remove PR residue. Electroplating was carried out at a plating current density of about 10 mA/cm². PR stripping was carried out using a stripping solution. Due to the positive tone of the PR, no residue is left after stripping.

Mask-less lithography (MLL) systems, also known as ‘Direct Laser Write (LDW)’ systems, use a rasterized or vectorized laser beam to expose the pattern from a CAD design. MLL systems have recently become very popular for panel substrate manufacturing, mainly in fan-out packages [94,95]. There are many advantages offered by MLL. With the use of a laser source, the resolution achievable with MLL is dependent on the laser beam diameter and it's much smaller than the resolutions of conventional aligners and steppers. MLL systems differ from traditional aligners and steppers in one key aspect-the directionality of radiation. A laser is a highly coherent and collimated beam of light having parallel rays resulting in minimal divergence as it propagates [96]. This can result in a high DoF, which is not achievable with the traditional systems. MLL systems have been reported to have DoF as high as ±12 μm [97].

In an example implementation, Heidelberg MLA-150 was used for the fabrication of fine-line RDL. FIG. 5B shows the SEM image of electroplated 1 μm traces formed using MLA-150. RDL traces with zero taper were formed in a 5 μm thick photoresist denoting a Depth-ofFocus (DoF) of greater than ±5 μm. Furthermore, dynamic autofocus of MLA-150 was found to be useful in correcting aberrations due to non-planarity, thickness variations, and substrate warpage.

Glass can have numerous advantages over conventional organic laminates for fine-line patterning [30]. Ultra-low roughness (R_{RMS}<1 nm) of glass can be advantageous in minimizing diffused reflections at the copper seed layer-photoresist interface, thus enabling very fine lithographic dimensions. FIG. 5B shows the smoothness of the copper seedlayer on glass. Furthermore, the tunable coefficient of thermal expansion (CTE) of glass can be used to minimize the warpage of the substrate, enabling ultra-high IO density multilayer RDL packages.

Example Materials and Processes for 2 μm microvias and <1 μm alignment. Via formation in package substrates can be carried out using laser drilling for both blind microvias as well as through vias. Laser drilling utilizes a concentrated laser beam that is used to ablate the polymer material. In this method, the microvia diameter achievable is limited by the laser beam diameter as well as the wavelength of the laser source. UV lasers are used due to the interaction of UV radiation with polymers. However, UV laser drilling can be limited with respect to microvia formation. Next-generation IO pitches require microvia diameters <5 μm, which is difficult to achieve using laser systems. Photovia is one of the options being adopted by the industry for <5 μm microvias. However, ULK dielectrics, such as parylenes, are not photosensitive. Furthermore, they are not designed for laser-via drilling. The higher melting point and thermal stability of Parylene-HT impose challenges with regard to laser drilling.

FIG. 5 shows microvia with diameter 3.1 μm diameter drilled in 3.5 μm thick Parylene-HT using ESI Cornerstone picosecond UV laser. The laser drilling parameters were—Power=0.06 W, Pulses=10, Z-offset=30 μm. Parylene-HT has a very high melting point of 550 °C, which makes it very challenging to ablate the polymer. Furthermore, a lot of debris is created, as seen in the image before plasma cleaning. Plasma cleaning can remove the debris, although it results in reduced dielectric thickness. The shape of the microvia is very uneven with a very low yield. For the given laser settings, very few microvias were opened. The laser power used was very low and comparable to the laser power fluctuations. In addition, for thermo-mechanical reliability of finer microvias, it is very critical to accurately control the microvia shape and height which is clearly not possible with laser drilling. For all these reasons, laser drilling of microvias in ULK dielectrics is not feasible.

Process for microvia formation in ULK dielectrics. The study developed for the formation of microvias in ULK dielectrics.

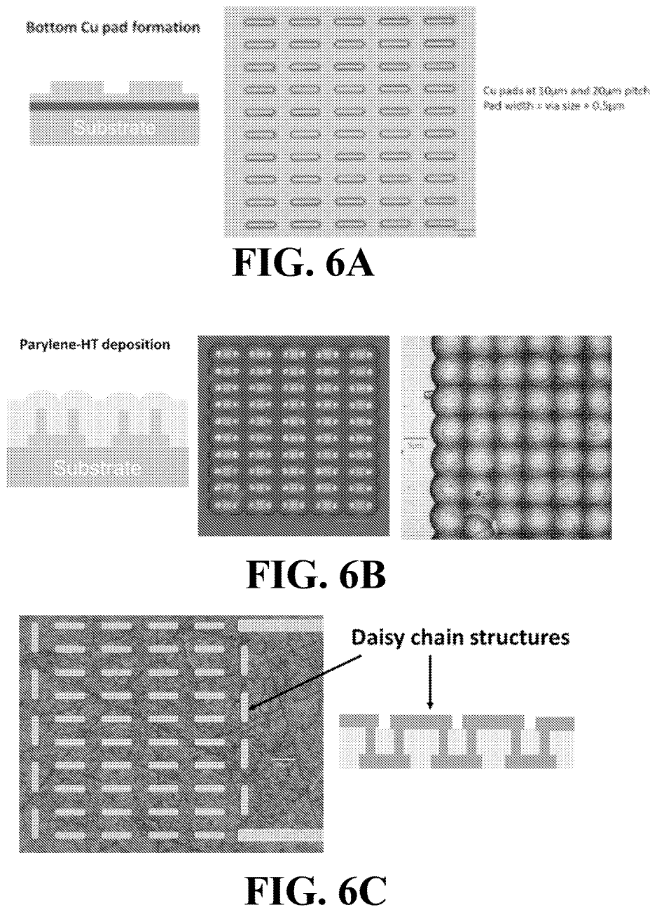

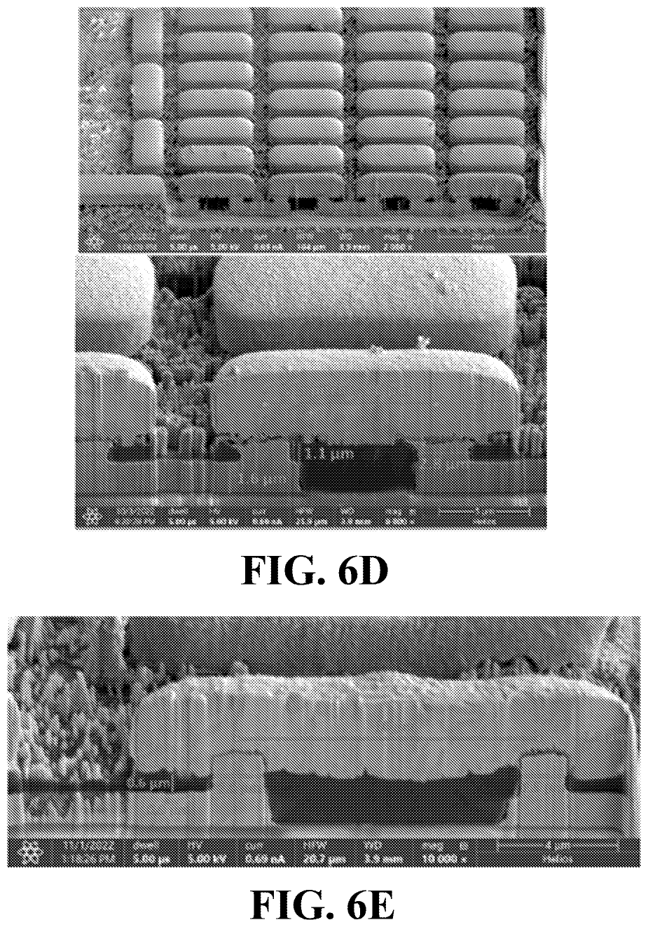

The method involves seed layer deposition on a desired substrate. In the study, glass was used directly as a substrate without an intermediate dielectric. The substrate with seed layer was used for the formation of copper pads. In this study, microvias with diameters 2-4 μm were targeted. The Cu pad width was designed to be 0.5 μm larger than the via size, i.e., alignment tolerance of ±0.25 μm. The via pitch of 10 and 20 μm was targeted. FIG. 6A shows the optical images of Cu pads with 3.5 μm width and 20 μm pitch. Positive photoresist was used for patterning, and the process parameters were the same as described in the earlier sections. The Cu seed layer was not etched after the formation of Cu pads.

After the formation of via landing pads, to form the vias, Cu pillars were plated on top of the pads utilizing the Cu seedlayer. In the study, the minimum via diameter of 1.6 μm was resolved with a relatively lower yield. Vias with diameters 2.5 μm and above were resolved with 100% yield.

The method can further include a dielectric deposition step. In the study, Parylene-HT was deposited using the Specialty Coating Systems and their proprietary process. A total thickness of 6 μm was deposited conformally, covering the pillars and Cu pads. Conformal deposition resulted in an overburden of 1-2 μm over the flat regions and 5-6 μm over the Cu pillars. FIG. 6B shows the 2 μm pillars with conformally deposited Parylene-HT.

Before the formation of the top metal layer, the overburden dielectric was removed to open the vias for electrical connection. Mechanical planarization was performed using a Logitech LP50 lapper. Alumina slurry having 1 μm particle size was used for removing the excess material. The substrates were polished until the dielectric overburden was completely removed, and vias were slightly polished. Opening of vias was confirmed using laser profilometry function in Keyence VK-X3000 optical profiler. The laser profilometry was able to differentiate between copper and polymer better than optical wavelength as seen from the contrast difference in FIG. 6B. A challenge in this step is dielectric residue preventing electrical contact between the top metal layer and the vias. Finer alumina particle size is desired as large particle sizes result in excessive mechanical deformation. In the study, 1 μm alumina slurry caused excessive deformation in <3 μm vias.

Subsequently, a top metal layer was formed using conventional SAP steps described earlier. FIG. 6C shows the top metal layer completing the daisy chain structure of 3 μm vias at 20 μm pitch. The alignment marks also get polished during the planarization step and are deformed thus lowering the alignment accuracy. The top metal layer is designed with ±1 μm tolerance as compared to ±0.25 μm tolerance for the via alignment.

FIG. 6D shows an FIB cross-section of 3 μm diameter via a daisy chain structure of 100 vias built using an example method described herein. Via height was 1 μm after planarization with a via pitch of 10 μm. The top pad-via interface appears rough due to the mechanical planarization step. Dielectric residue between the pad and via is another challenge causing the discontinuity. Better planarization process control is necessary to mitigate these issues.

FIG. 6E shows the daisy chain structure with the minimum via diameter of 1.6 μm and 10 μm pitch. This process can be used to scale microvias further down to <5 μm pitch for the next generation of higher IO density substrates.

Microvia reliability assessment in ULK dielectrics. Finite element analysis was also performed of the vias. Experimental results showed the modeled vias were able to withstand a number of cycles of failure greater than 1000.

Microvias need to sustain a thousand thermal cycles as per the JEDEC standard to pass the reliability criteria. With the reduction in microvia diameter, the strain in the via increases, and thus fatigue life decreases. At a certain point, the total strain range is too high for the via to be reliable. An FEA model was utilized to determine the critical via diameter at which the via reliability hits the limits. Conventional laser-drilled microvias have a taper due to the Gaussian distribution of laser power. Thus, the maximum possible via angle with laser drilling is about 80°. For the modeling study, a via geometry with 80° via angle and aspect ratio of 1 was considered. The via geometry represents the best case of conventional laser-drilled via. Polymer dielectric properties were as follows—CTE=35 ppm/K, elastic modulus=2.5 GPa. The properties represent the best-case properties for an epoxy-based dielectric commonly used in substrate packaging. The design and material parameters were used for simulating the total strain range and the results. It was observed that at 2 μm via-diameter, the number of cycles to failure is less than 1000, thus not satisfying the JEDEC criteria. This represents the fundamental limit below which the strain in the via is too high to be reliable.

A technique for microvia reliability improvement is developed based on the simulation results, which is described in P. Nimbalkar, M. Kathaperumal, F. Liu, M. Swaminathan, and R. Tummala, “Reliability modeling of micro-vias in high-density redistribution layers,” in 2021 IEEE 71st Electronic Components and Technology Conference (ECTC), 2021, pp. 983-988.

Via geometries with 80° and 90° via angles were created. A vertical groove was made in the bottom copper pad. Plating from the bottom of the groove to the top of the dielectric creates a via structure. Parylene-HT was used as a dielectric for the study. The via geometry was subject to thermal cycling, and the strain was measured at the bottom edge of the groove.

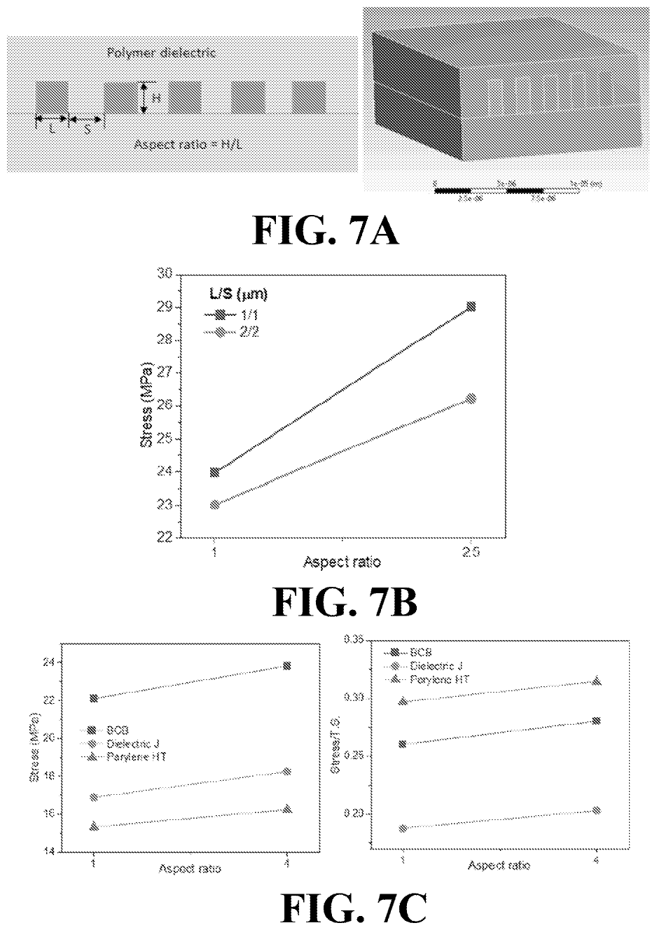

Polymer reliability. Polymer dielectrics are susceptible to fatigue cracking during thermal cycling. The study developed a finite element model in ANSYS for simulating the stresses developed in the polymer during thermal cycling. The test geometry used in this model was created using SolidWorks (FIG. 7A).

The geometry consists of copper traces embedded in polymer dielectric. Periodic and symmetric boundary conditions were applied on the sides of the geometry. The bottom of the geometry was constrained to account for the effect of the substrate. A multilinear kinematic hardening model [99] was used for copper, and polymers were modeled as linear elastic. Polymer dielectric was modeled as linear elastic with a glass transition temperature of 180 °C. Because of the unavailability of temperature-dependent CTE and elastic modulus of copper and polymer, they were assumed to be constant. The geometry was subject to thermal cycling from −55 °C to 125 °C. Because of the shorter duration and lower number of cycles, the effect of pre-conditioning is supposed to be minimal.

Polymer cracking in RDL occurs at the copper-polymer interfaces, especially at the corners and the edges of copper features. The stresses developed in the region surrounding the copper traces were evaluated using this model. The effect of RDL L/S and aspect ratio on stress is shown in FIG. 7B. As the RDL dimensions are reduced, the stress in the dielectric increases. Also, stress increases with an increase in the aspect ratio of wires. ULK polymer dielectric candidates were simulated to determine their reliability for 1 m RDL. The results are shown in FIG. 7C.

The effect of elastic modulus and CTE of polymer is apparent from the stress values. Parylene-HT shows the lowest stress because of its low CTE and modulus. As discussed in the previous chapter, the cracking in polymer dielectrics is due to fatigue. However, the fatigue models need to be determined empirically. Therefore, the stress in polymers is represented as the ratio of the tensile strength (FIG. 7B, subpanel B). The probability of fatigue failure should be low as the stress is about 30% of the tensile strength. Therefore, all three dielectric candidates seem quite reliable in terms of polymer cracking reliability.

Adhesion reliability. In an advanced semi-additive process (SAP), a copper seed layer is sputter deposited on the polymer with titanium as an intermediate layer. Sputtering conditions have a significant effect on the adhesion of the seed layer to polymer dielectric. Sputtering parameters such as current, voltage, sputter gas pressure, etc., affect the plasma conditions, which in turn affect the sputtering characteristics. Adhesion of the seed layer is the result of complex metal-polymer interactions, as discussed in the earlier chapters. The effect of sputter deposition rates of titanium and copper on adhesion was studied. Ti and Cu deposition rates were varied individually, keeping the other constant and adhesion strength was measured with respect to each deposition rate.

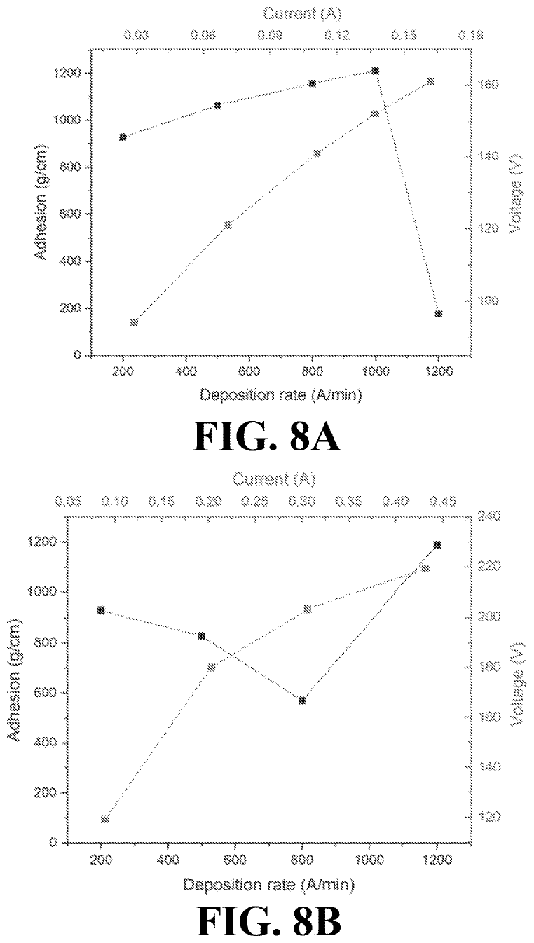

FIG. 8A shows the effect of the Cu deposition rate on adhesion. For the study, the Ti deposition rate was kept constant at 200 A°/min. As the deposition rate is increased, the sputtering voltage increases which increases the energy of sputtered atoms. Therefore, adhesion strength improves as more copper atoms diffuse in bulk, causing better mechanical/chemical interlocking. After 1000 A°/min, the atomic flux of sputtered atoms is too high, resulting in the aggregation of copper atoms. This results in lower adhesion strength.

FIG. 8B shows the effect of the Ti deposition rate on adhesion. In the study, the Cu deposition rate was kept constant at 200 A°/min. With the increase in deposition rate, the sputtering current increases, which increases the atomic flux of sputtered atoms. Therefore, adhesion strength decreases as more copper atoms aggregate rather than diffuse in the bulk. After 800 A°/min, the energy of sputtered atoms is too high, resulting in the diffusion of copper atoms inside bulk, leading to better mechanical/chemical interlocking. This was observed to provide results with higher adhesion strength.

Pre-sputtering process for enhanced adhesion. Plasma processing before metal deposition significantly affects the metal-polymer interactions. The conventional pre-sputtering process involves argon plasma treatment followed by Ti—Cu seed sputtering. A modified pre-sputtering process was developed to enhance the adhesion of metal seed with the polymer [101]. The sequence of steps is as follows—argon plasma etch→oxygen plasma etch→pre-bake in vacuum→Ti and Cu seed sputtering→electroplating of Cu.

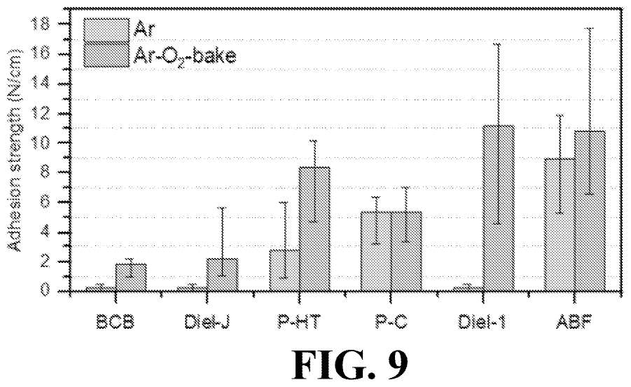

FIG. 9 shows a summary of the results of adhesion strength measurements of six dielectrics investigated in this study. It can be seen that the Ar—O2-bake process resulted in a significant increase in the adhesion strength compared to the Ar plasma process for five of the six dielectrics. The highest increase in mean adhesion strength was observed for Diel-1 from 0.25 N/cm with Ar to 11.2 N/cm with Ar—O2-bake. Similarly, ABF showed an increase in mean adhesion strength from 8.9 N/cm to 10.8 N/cm. ABF also showed the highest maximum adhesion strength of 17.7 N/cm. BCB and Diel-J showed poor adhesion strength of 0.25 N/cm with Ar treatment. Here, 0.25 N/cm corresponds to the minimum measurable adhesion using the peel tester. Ar—O2-bake treatment resulted in a slight increase in adhesion for both BCB and Diel-1. P-HT showed an increase in adhesion from 2.7 N/cm to 8.4 N/cm. P-C showed a minimal increase in mean adhesion strength from 5.3 N/cm to 5.4 N/cm.

The increase in adhesion strength was independent of the chemistry of the dielectric. There can be two mechanisms of adhesion-mechanical and chemical. Mechanical bonding involves the physical interlocking of two adhesive surfaces due to the roughness of the interfaces. Chemical bonding involves chemical interaction between the deposited metal and polymer. In order to elucidate the contribution of the mechanical component, roughness measurements were performed.

It was observed that the differences in the roughness values were insignificant and did not explain the higher adhesion values for the Ar—O2-bake process. Usually, a significant increase in surface roughness is necessary to observe the kind of adhesion enhancement observed in this study. Therefore, in the results, the contribution of mechanical bonding to adhesion enhancement was expected and observed to be minimal.

a. Materials and methods. Six different polymer dielectrics with different polymer chemistries were used in this study. The dielectrics are labeled as ABF, BCB, P-C (Parylene-C), PHT (Parylene-HT), Diel-J, and Diel-1. ABF-GX92 (Ajinomoto Build-up Film) is a commercially available polymer dielectric widely used in the electronics industry. ABF is a silica-filled dielectric with epoxy as the polymer matrix. BCB (Benzocyclobutene) polymer was obtained from Dow (Trade name: BCB Cyclotene 6505). BCB is also a popular photo-initiated dielectric used in the electronics industry for a variety of applications. Parylene-C and Parylene-HT are commercially available polymer coatings developed by Specialty Coating Systems (SCS). Parylene is the name for a group of polymers based on poly(para-xylylene). Parylene-C is chlorine-substituted, while Parylene-HT is a fluorine-substituted version. Diel-J and Diel-1 are research-grade polymer dielectrics obtained from our industry partners. Polymer dielectrics were applied onto 4-inch silicon or FR4 substrates for the experiments. ABF and Diel-1 were laminated using a Meiki vacuum laminator. Parylene-C was vapor deposited using SCS Labcoater PDS 2010. Parylene-HT coated samples were received from SCS Inc. BCB and Diel-1 were spin-coated on silicon wafers. Polymer dielectrics were subjected to two types of pre-sputtering plasma processes. The first process (denoted as Ar) involved standard argon plasma treatment (150 W, 50 sccm, 8.5 mins) using Oxford End-point RIE. The second process (denoted as—Ar—O2-bake) involved Argon plasma followed by oxygen plasma (200 W, 40 sccm, 2 mins) followed by baking (125 °C, 5 mTorr, 30 mins) in a vacuum oven (Heraeus vacuum oven). Adhesion samples were deposited with 50 nm titanium seed followed by a 200 nm copper seed layer by DC sputtering (Unifilm sputterer). It was followed by electroplating of 20-25 μm copper at a plating current of 1-1.5 A/dm2. Copper was electroplated under galvanostatic conditions using Atotech's Cupracid TP electrolyte solution. Samples with electroplated copper were annealed at 2000 °C for 1 hour under a nitrogen environment. For XPS experiments, samples pre-treated with two plasma processes (Ar and Ar—O2-bake) were deposited with 10 nm of titanium seed layer. For roughness measurements and FTIR scans, pre-treated samples were used without any further processing.

b. Characterization. The interfacial adhesion between the dielectric and copper was quantified using a 90° peel tester (Testing Machines Inc.). Peel tests were performed on 1-cm wide metal strips at a peel rate of 30.5 cm/min. The substrates were carefully taped onto the base metal plate to ensure that the substrate warpage did not influence the measured peel strength.

Thermal cycling reliability of multi-layer structure. The thermal cycling reliability of microvias in polymer dielectrics was evaluated using daisy chain test structures of 100 micro vias. The samples were exposed to pre-conditioning followed by air-to-air thermal cycling as per JEDEC JESD 22-A104D. Preconditioning involved baking at 125 °C for 24 hours, followed by moisture soak (Level 3: 60 °C, 60% RH for 40 hours) and three cycles of lead-free solder reflow with a peak temperature of 260 °C. The temperature cycling range was −55 °C to 125 °C with a ramp rate of 15 °C/min and a hold time of one minute at the extremes. The electrical resistances of the daisy chain structures were measured using a four-point probe method every 100 cycles. A total increase in electrical resistance of >20% was considered to be a failure.

Results showed that, for 4 μm vias at 10 μm pitch, the resistance increase was 22% of the original value. Daisy chains with 4 μm vias at 20 μm pitch showed higher resistance due to the larger pitch and longer daisy chain. The net increase in resistance was 15% at 1000 thermal cycles, thus passing the reliability criteria.

It was observed that the interfaces between the via and Cu pads were intact with no fatigue cracking or defects. The low aspect ratio of vias may explain the lower strain thus better reliability. Furthermore, no cracks or failure was observed in the dielectric due to its lower CTE and elastic modulus. This is in agreement with the modeling performed in the study.

Highly Accelerated Stress Test. Change in adhesion of Cu with Parylene-HT was evaluated after the Highly Accelerated Stress Test (HAST). The test was performed as per the JEDEC JESD 22-A110 reliability standard. The test parameters were performed at a temperature of 130 °C at 85% relative humidity and a duration of 96 hours. The test samples were subject to MSL-3 preconditioning per JEDEC JESD 22-A113 before HAST. Preconditioning involved baking at 125 °C for 24 hours followed by moisture soak (Level 3: 60 °C, 60% RH for 40 hours) and three cycles of lead-free solder reflow with a peak temperature of 260 °C. A slight reduction in adhesion strength was observed for both types of plasma treatments. For the Ar—O2-bake treated substrate, the adhesion value was reduced from 8.4 N/cm before HAST to 5.2 N/cm after HAST. The adhesion strength of >5 N/cm was considered sufficient for RDL reliability. Therefore, the Ar—O2-bake treated substrate passed HAST reliability. Slightly higher adhesion strength were observed for Ar-treated sample is attributed to the statistical variation.

The test was also performed as per JEDEC reliability standard at 130 °C and 85% relative humidity for 100 hours. Micro-etch surface treatment was performed on copper to cause micro-roughening for mechanical interlocking for adhesion. Parylene-HT deposition was followed. Due to the chemical vapor deposition of Parylene-HT, it is polymerized at all contact surfaces, covering nanoscopic valleys and trenches, thus providing superior adhesion. From the evaluation, minimal delamination was observed after 100 hours of stress. No effect on Cu/Ti and glass interface can be seen, demonstrating the superior mechanical reliability of both glass and Parylene-HT RDL.

### Discussion

Conventional polymer dielectrics used in package substrates induce thermal and curing stresses on the wafer/panel substrates. Vapor deposition of polymers with spontaneous curing on substrates at ambient conditions reduces the thermal and curing stresses, thereby improving the ease of processing. Lower stresses also lead to lower warpage and improved thermomechanical reliability of package substrates. This enables larger body size package substrates for heterogeneous integration.

The example embodiments of the present disclosure described herein include the vapor deposition of polymers with spontaneous polymerization on substrates at ambient conditions reduces the thermal and curing stresses, thereby improving the ease of processing. Lower stresses also lead to lower warpage and improved thermomechanical reliability of package substrates. This enables larger body size package substrates for heterogeneous integration.

The exemplary system and method can include multiple benefits, including (i) capabilities to work with larger panel and body sizes possible with lower stresses and warpage, (ii) providing lower Dₖ as compared to inorganic dielectrics leading to lower capacitive losses, (iii) providing lower temperature processing compared to inorganic dielectrics, (iv) employing fewer thermal processing steps reduce the manufacturing costs, (v) being scalable to large panel formats, and (vi) providing thinner dielectric layers and overall thinner package substrates compared to traditional polymer-based package substrates.

In some embodiments of the present disclosure, the device includes a polymer dielectric deposited on a large wafer/panel package substrate such that it polymerizes on the substrate during the application/deposition so that further curing of the polymer is unnecessary. The deposition/polymerization may take place at ambient temperatures, leading to minimal/zero thermal stresses.

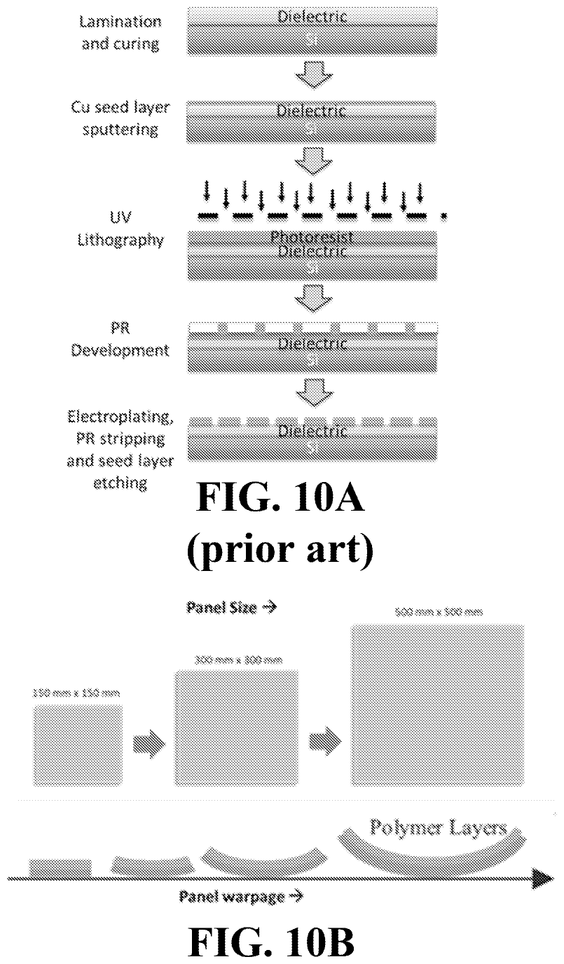

FIG. 10A shows an example conventional semi-additive process flow, e.g., used in package substrates, using vacuum lamination or liquid spin coating. Conventional vapor deposition pressures typically are <10⁻⁵ Torr. As shown in FIG. 10, the polymer dielectrics are cured as a part of the application process—the curing can induce stresses in the substrate due to curing shrinkage associated with these dielectrics. The shrinkages can occur due to the presence of solvent in these dielectrics. The curing stresses thus can cause warping of the substrates, especially when the panel sizes or package/substrate sizes are considerably large. Conventional polymer dielectrics often need to be cured before undergoing any further processing due to the inadequate mechanical stability of uncured dielectrics. The trend in semiconductor packaging is towards larger body/package/substrate sizes. Therefore, low-stress polymer dielectrics are critical to enable large body/package/substrate sizes with minimum warpage. FIG. 10B also shows size effects associated with larger and thinner wafers that can aggravate wafer warpage.

The curing processes can add significant costs to the conventional package substrates due to the multiple curing steps required for each layer of dielectric. Curing stresses can also cause cracking of fragile substrate materials such as glass. In contrast, the exemplary spontaneous polymerization reduces the chances of such cracking due to zero curing stresses.

In contrast, the exemplary system and method In some embodiments of the present disclosure, the device includes a package substrate with multiple polymer and metal layers where polymer build-up layers are deposited on a substrate in such a way that the polymer polymerizes on the substrate during deposition.

### Conclusion

Although example embodiments of the present disclosure are explained in some instances in detail herein, it is to be understood that other embodiments are contemplated. Accordingly, it is not intended that the present disclosure be limited in its scope to the details of construction and arrangement of components set forth in the following description or illustrated in the drawings. The present disclosure is capable of other embodiments and of being practiced or carried out in various ways.

In some embodiments, embodiments of the present disclosure can include a glass wafer or panel substrate with a polymer dielectric applied in such a way that the dielectric polymerizes on the glass substrate during deposition.

The exemplary system and method can be employed for packaged semiconductor devices that can be used in computing applications. As some non-limiting examples, embodiments of the present disclosure can be used for large semiconductor wafers configured for high-performance computing (e.g., data centers, artificial intelligence, 5G, mm-wave, base stations).

In some embodiments of the present disclosure, the package substrate can include a polymer dielectric as described herein conformally deposited onto the various RF components, followed by the deposition of a thin layer of a conductive material, metal, high-k dielectric and/or a composite for electromagnetic interference shielding.

It must also be noted that, as used in the specification and the appended claims, the singular forms “a,” “an,” and “the” include plural referents unless the context clearly dictates otherwise. Ranges may be expressed herein as from “about” or “approximately” one particular value and/or to “about” or “approximately” another particular value. When such a range is expressed, other exemplary embodiments include from the one particular value and/or to the other particular value.

By “comprising” or “containing” or “including” is meant that at least the name compound, element, particle, or method step is present in the composition or article or method, but does not exclude the presence of other compounds, materials, particles, method steps, even if the other such compounds, material, particles, method steps have the same function as what is named.

In describing example embodiments, terminology will be resorted to for the sake of clarity. It is intended that each term contemplates its broadest meaning as understood by those skilled in the art and includes all technical equivalents that operate in a similar manner to accomplish a similar purpose. It is also to be understood that the mention of one or more steps of a method does not preclude the presence of additional method steps or intervening method steps between those steps expressly identified. Steps of a method may be performed in a different order than those described herein without departing from the scope of the present disclosure. Similarly, it is also to be understood that the mention of one or more components in a device or system does not preclude the presence of additional components or intervening components between those components expressly identified.

The term “about,” as used herein, means approximately, in the region of, roughly, or around. When the term “about” is used in conjunction with a numerical range, it modifies that range by extending the boundaries above and below the numerical values set forth. In general, the term “about” is used herein to modify a numerical value above and below the stated value by a variance of 10%. In one aspect, the term “about” means plus or minus 10% of the numerical value of the number with which it is being used. Therefore, about 50% means in the range of 45%-55%. Numerical ranges recited herein by endpoints include all numbers and fractions subsumed within that range (e.g., 1 to 5 includes 1, 1.5, 2, 2.75, 3, 3.90, 4, 4.24, and 5).

Similarly, numerical ranges recited herein by endpoints include subranges subsumed within that range (e.g., 1 to 5 includes 1-1.5, 1.5-2, 2-2.75, 2.75-3, 3-3.90, 3.90-4, 4-4.24, 4.24-5, 2-5, 3-5, 1-4, and 2-4). It is also to be understood that all numbers and fractions thereof are presumed to be modified by the term “about.”

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that an order be inferred, in any respect. This holds for any possible non-express basis for interpretation, including: matters of logic with respect to arrangement of steps or operational flow; plain meaning derived from grammatical organization or punctuation; the number or type of embodiments described in the specification.

While the methods and systems have been described in connection with certain embodiments and specific examples, it is not intended that the scope be limited to the particular embodiments set forth, as the embodiments herein are intended in all respects to be illustrative rather than restrictive.

The following patents, applications, and publications, as listed below and throughout this document, are hereby incorporated by reference in their entirety herein.

### REFERENCES

[1] S. Hou, W. C. Chen, C. Hu, C. Chiu, K. Ting, T. Lin, W. Wei, W. Chiou, V. J. Lin, V. C. Chang, et al., “Wafer-level integration of an advanced logic-memory system through the second-generation cowos technology,” IEEE Transactions on Electron Devices, vol. 64, no. 10, pp. 4071-4077, 2017.
[2] K. Oi, S. Otake, N. Shimizu, S. Watanabe, Y. Kunimoto, T. Kurihara, T. Koyama, M. Tanaka, L. Aryasomayajula, and Z. Kutlu, “Development of new 2.5 d package with novel integrated organic interposer substrate with ultra-fine wiring and high density bumps,” in 2014 IEEE 64th Electronic components and technology conference (ECTC), IEEE, 2014, pp. 348-353.
[3] J. Kim, I. Choi, J. Park, J.-E. Lee, T. Jeong, J. Byun, Y. Ko, K. Hur, D.-W. Kim, and K. S. Oh, “Fan-out panel level package with fine pitch pattern,” in 2018 IEEE 68th Electronic Components and Technology Conference (ECTC), IEEE, 2018, pp. 52-57.
[4] R. W. Keyes, “Physical limits of silicon transistors and circuits,” Reports on Progress in Physics, vol. 68, no. 12, p. 2701, 2005.
[5] H. N. Khan, D. A. Hounshell, and E. R. Fuchs, “Science and research policy at the end of moore's law,” Nature Electronics, vol. 1, no. 1, pp. 14-21, 2018.
[6] W. Nawrocki, “Physical limits for scaling of integrated circuits,” in Journal of Physics: Conference Series, IOP Publishing, vol. 248, 2010, p. 012 059.
[7] P. A. Packan, “Pushing the limits,” Science, vol. 285, no. 5436, pp. 2079-2081, 1999.
[8] R. R. Tummala, “Moore's law for packaging to replace moore's law for ics,” in 2019 Pan Pacific Microelectronics Symposium (Pan Pacific), IEEE, 2019, pp. 1-6.
[9] C.-L. Liang, Y.-S. Lin, C.-L. Kao, D. Tarng, S.-B. Wang, Y.-C. Hung, and K.-L. Lin, “Electromigration failure study of a fine-pitch 2 m/2 m l/s cu redistribution line embedded in polyimide for advanced high-density fan-out packaging,” in 2020 IEEE 70th Electronic Components and Technology Conference (ECTC), IEEE 2020, pp. 361-366.
[10] C.-L. Liang, Y.-S. Lin, C.-L. Kao, D. Tarng, S.-B. Wang, Y.-C. Hung, G.-T. Lin, and K.-L. Lin, “Electromigration reliability of advanced high-density fan-out packaging with fine-pitch 2 lm/2 lm l/s cu redistribution line,” IEEE Transactions on Components, Packaging and Manufacturing Technology, 2020.
[11] R. Furuya, H. Lu, F. Liu, H. Deng, T. Ando, V. Sundaram, and R. Tummala, “Demonstration of 2 m rdl wiring using dry film photoresists and 5 m rdl via by projection lithography for low-cost 2.5 d panel-based glass and organic interposers,” in 2015 IEEE 65th Electronic Components and Technology Conference (ECTC), IEEE, 2015, pp. 1488-1493.
[12] D.-C. Hu, W.-L. Yeh, Y.-H. Chen, and R. Tain, “2/2 μm embedded fine line technology for organics interposer applications,” in 2016 IEEE 66th Electronic Components and Technology Conference (ECTC), IEEE, 2016, pp. 147-152.
[13] I.-H. Tseng, K.-c. Shie, B. T.-H. Lin, C.-C. Chang, and C. Chen, “Electromigration in 2 m redistribution lines and cu-cu bonds with highly; 111 ¿-oriented nanotwinned cu,” in 2020 IEEE 70th Electronic Components and Technology Conference (ECTC), IEEE, 2020, pp. 479-484.
[14] H. Kudo, R. Kasai, J. Suyama, M. Takeda, Y. Okazaki, H. Iida, D. Kitayama, T. Sasao, K. Sakamoto, H. Sato, et al., “Demonstration of high electrical reliability of sub-2 micron cu traces covered with inorganic dielectrics for advanced packaging technologies,” in 2017 IEEE 67th Electronic Components and Technology Conference (ECTC), IEEE, 2017, pp. 1849-1854.
[15] S. Watanabe, “Development of organic multi chip package for high performance application,” in iNEMI Substrate & Packaging Technology Workshop, 2014.
[16] M. Ishida, “Apx (advanced package x)-advanced organic technology for 2.5 d interposer,” in 2014 CPMT Seminar, Latest Advances in Organic Interposers, 2014, pp. 27-30.
[17] R. Tummala, M. Swaminathan, and P. Nimbalkar, “A new and historic packaging era,” Chip Scale Review, pp. 6-10, 2022.
[18] I. Hsu, C.-Y. Chen, S. Lin, T.-J. Yu, M.-C. Hsieh, K. Kang, and S. W. Yoon, “Fine-pitch interconnection and highly integrated assembly packaging with fomip (fan-out mediatek innovation package) technology,” in 2020 IEEE 70th Electronic Components and Technology Conference (ECTC), IEEE, 2020, pp. 867-872.
[19] W.-S. Kwon, S. Ramalingam, X. Wu, L. Madden, C. Huang, H.-H. Chang, C.-H. Chiu, S. Chiu, and S. Chen, “Cost effective and high performance 28 nm fpga with new disruptive silicon-less interconnect technology (slit),” in International symposium on microelectronics, International Microelectronics Assembly and Packaging Society, vol. 2014, 2014, pp. 000 599-000 605.
[20] JCET. (2019). “Embedded wafer-level ball grid array technology.”
[21] C. Zwenger, R. Huemoeller, J. Kim, D. Kim, W. Do, and S. Seo, “Silicon wafer integrated fan-out technology,” Additional Papers and Presentations, vol. 2015, no. DPC, pp. 000 217-000 247, 2015.
[22] J.-K. Fang, M.-L. Huang, H.-J. Tu, W.-L. Lu, and P. Yang, “A production-worthy fan-out solution-ase focos chip last,” in 2020 IEEE 70th Electronic Components and Technology Conference (ECTC), IEEE, 2020, pp. 290-295.
[23] H.-P. Pu, H. Kuo, C. Liu, and C. Douglas, “A novel submicron polymer re-distribution layer technology for advanced info packaging,” in 2018 IEEE 68th Electronic Components and Technology Conference (ECTC), IEEE, 2018, pp. 45-51.
[24] R. Huemoeller, “Amkor's slim & swift package technology,” Amkor Technology, SVP Advanced Package Technology Develop & IP, 2015.
[25] R. Mahajan, Z. Qian, R. S. Viswanath, S. Srinivasan, K. Ayg\ddot{ }un, W.-L. Jen, S. Sharan, and A. Dhall, “Embedded multidie interconnect bridge—a localized, highdensity multichip packaging interconnect,” IEEE Transactions on Components, Packaging and Manufacturing Technology, vol. 9, no. 10, pp. 1952-1962, 2019.
[26] 3Dincites. (2020).
[27] L. Li, P. Chia, P. Ton, M. Nagar, S. Patil, J. Xue, J. Delacruz, M. Voicu, J. Hellings, B. Isaacson, et al., “3d sip with organic interposer for asic and memory integration,” in 2016 IEEE 66th Electronic Components and Technology Conference (ECTC), IEEE, 2016, pp. 1445-1450.
[28] T. Yamada, “Organic interposer and embedded substrate,” in 2015 Packaging Symposium, Kyocera America, Inc, 2015.
[29] P. A. Kohl, “Low-dielectric constant insulators for future integrated circuits and packages,” Annual review of chemical and biomolecular engineering, vol. 2, pp. 379-401, 2011.
[30] R. Tummala, B. Deprospo, S. Dwarakanath, S. Ravichandran, P. Nimbalkar, N. Nedumthakady, and M. Swaminathan, “Glass panel packaging, as the most leadingedge packaging: Technologies and applications,” in 2020 Pan Pacific Microelectronics Symposium (Pan Pacific), 2020, pp. 1-5.
[31] C. Nair, “Modeling, design, materials, processes and reliability of multi-layer redistribution wiring layers on glass substrates for next generation of high-performance computing applications,” Ph.D. dissertation, Georgia Institute of Technology, 2019.
[32] B. DeProspo, “Modeling, design and demonstration of 1 m wide low resistance panel redistribution layer technology for high performance computing applications,” Ph.D. dissertation, Georgia Institute of Technology, 2020.
[33] D. Opp, D. Skinner, and R. Wiktorek, “A model for polymer fatigue,” Polymer Engineering & Science, vol. 9, no. 2, pp. 121-130, 1969.
[34] J. Williams, “A model of fatigue crack growth in polymers,” Journal of Materials Science, vol. 12, no. 12, pp. 2525-2533, 1977.
[35] H. F. Mark, Encyclopedia of polymer science and technology, concise. John Wiley & Sons, 2013.
[36] R. W. Hertzberg, H. Nordberg, and J. Manson, “Fatigue crack propagation in polymeric materials,” Journal of Materials Science, vol. 5, no. 6, pp. 521-526, 1970.
[37] J. Sauer and G. Richardson, “Fatigue of polymers,” International journal of fracture, vol. 16, no. 6, pp. 499-532, 1980.
[38] J. Sauer and M. Hara, “Effect of molecular variables on crazing and fatigue of polymers,” in Crazing in Polymers Vol. 2, Springer, 1990, pp. 69-118.
[39] S. Hegde, R. V. Pucha, and S. K. Sitaraman, “Enhanced reliability of high density wiring (hdw) substrates through new dielectric and base substrate materials,” in ASME International Mechanical Engineering Congress and Exposition, vol. 36487, 2002, pp. 283-290.
[40] S. Mahalingam, S. Hegde, G. Ramakrishna, R. V. Pucha, and S. K. Sitaraman, “Material interaction effects in the reliability of high density interconnect (hdi) boards,” in ASME International Mechanical Engineering Congress and Exposition, vol. 37149, 2003, pp. 165-170.
[41] S. Mahalingam, S. Hegde, J. Ahmad, R. V. Pucha, V. Sundaram, F. Liu, G. White, R. Tummala, and S. K. Sitaraman, “Materials, processes and reliability of mixedsignal substrates for sop technology,” in 2004 Proceedings. 54th Electronic Components and Technology Conference (IEEE Cat. No. 04CH37546), IEEE, vol. 2, 2004, pp. 1630-1635.
[42] S. S. Manson, Behavior of materials under conditions of thermal stress. National Advisory Committee for Aeronautics, 1953, vol. 2933.
[43] S. S. Manson and T. Dolan, Thermal stress and low cycle fatigue, 1966.
[44] W. Engelmaier, “Fatigue life of leadless chip carrier solder joints during power cycling,” IEEE transactions on components, hybrids, and manufacturing technology, vol. 6, no. 3, pp. 232-237, 1983.
[45] K. Yamanaka, T. Fujisaki, M. Ichinose, and T. Ooyoshi, “Effect of geometry and dielectric material on thermo-mechanical strain on micro-vias in build-up substrates,” Journal of Materials Science: Materials in Electronics, vol. 21, no. 9, pp. 943-949, 2010.
[46] G. Ramakrishna, F. Liu, and S. Sitaraman, “Experimental and numerical investigation of microvia reliability,” in ITherm 2002. Eighth Intersociety Conference on Thermal and Thermomechanical Phenomena in Electronic Systems (Cat. No. 02CH37258), IEEE, 2002, pp. 932-939.
[47] F. Su, R. Mao, J. Xiong, K. Zhou, Z. Zhang, J. Shao, and C. Xie, “On thermomechanical reliability of plated-through-hole (pth),” Microelectronics Reliability, vol. 52, no. 6, pp. 1189-1196, 2012.
[48] G. Ramakrishna, F. Liu, and S. K. Sitaraman, “Role of dielectric material and geometry on the thermo-mechanical reliability of microvias,” in 52nd Electronic Components and Technology Conference 2002.(Cat. No. 02CH37345), IEEE, 2002, pp. 439-445.
[49] S. Mahalingam, S. Hegde, G. Ramakrishna, R. V. Pucha, and S. K. Sitaraman, “Material interaction effects in the reliability of high density interconnect (hdi) boards,” in ASME International Mechanical Engineering Congress and Exposition, vol. 37149, 2003, pp. 165-170.
[50] Y. Ning, M. H. Azarian, and M. Pecht, “Influence of plating quality on reliability of microvias,” IPC APEX Expo, 2015.
[51] P. Nimbalkar, F. Liu, A. Watanabe, D. Weyers, M. Kathaperumal, C. P. Lin, F. Naohito, T. Makita, N. Watanabe, A. Kubo, M. Swaminathan, and R. Tummala, “Fabrication and reliability demonstration of 5 m redistribution layer using lowstress dielectric dry film,” in 2020 IEEE 70th Electronic Components and Technology Conference (ECTC), 2020, pp. 62-67.
[52] D. Kovach, N. Amirgulyan, C.-P. CHIEN, and M. Tanielian, “Minimizing stress in cu/polyimide processes for large format mem manufacturing,” The International journal of microcircuits and electronic packaging, vol. 23, no. 1, pp. 70-77, 2000.
[53] S. Chen, C. Yang, F. Faupel, and P. Ho, “Stress relaxation during thermal cycling in metal/polyimide layered films,” Journal of applied physics, vol. 64, no. 12, pp. 6690-6698, 1988.
[54] S. Lagrange, S. Brongersma, M. Judelewicz, A. Saerens, I. Vervoort, E. Richard, R. Palmans, and K. Maex, “Self-annealing characterization of electroplated copper films,” Microelectronic Engineering, vol. 50, no. 1-4, pp. 449-457, 2000.
[55] T. Hara, H. Toida, and Y. Shimura, “The self-annealing phenomenon in copper interconnection,” Electrochemical and Solid State Letters, vol. 6, no. 7, G 98, 2003.
[56] H. Matsuyama, T. Suzuki, T. Nakamura, M. Shiozu, H. Ehara, M. Oshima, T. Soeda, H. Hosoi, and K. Yamabe, “Voiding generation in copper interconnect under room temperature storage in 12 years,” Japanese Journal of Applied Physics, vol. 56, no. 7S2, 07KG01, 2017.
[57] H. Matsuyama, T. Suzuki, M. Shiozu, H. Ehara, T. Soeda, H. Hosoi, M. Oshima, and K. Yamabe, “Verification of copper stress migration under low temperature long time stress,” in 2019 IEEE International Reliability Physics Symposium (IRPS), IEEE, 2019, pp. 1-5.
[58] C. Zhu, W. Ning, G. Xu, and L. Luo, “Stress evolution during thermal cycling of copper/polyimide layered structures,” Materials science in semiconductor processing, vol. 27, pp. 819-826, 2014.
[59] M. Horiuchi, T. Yamasaki, and Y. Shimizu, “Metallization technologies on a smooth resin surface for the next generation of flip chip packaging,” Transactions of The Japan Institute of Electronics Packaging, vol. 3, no. 1, pp. 110-115, 2010.
[60] K. Inoue, K. Matsui, M. Watanabe, and H. Honma, “Surface modification of polyimide using uv light and formation of circuit patterns,” Journal of The Surface Finishing Society of Japan, vol. 59, no. 1, pp. 47-47, 2008.
[61] Y. Oh, E. J. Kim, Y. Kim, K. Choi, W. B. Han, H.-S. Kim, and C. S. Yoon, “Adhesion of sputter-deposited cu/ti film on plasma-treated polymer substrate,” Thin Solid Films, vol. 600, pp. 90-97, 2016.
[62] J. F. Friedrich, I. Koprinarov, R. Giebler, A. Lippitz, and W. E. S. Unger, “Reactions and intermediates at the metal-polymer interface as observed by xps and nexafs spectroscopy,” The Journal of Adhesion, vol. 71, no. 2-3, pp. 297-321, 1999. eprint: https://doi.org/10.1080/00218469908014853.
[63] S. H. Kim, S. W. Na, N.-E. Lee, Y. W. Nam, and Y.-H. Kim, “Effect of surface roughness on the adhesion properties of cu/cr films on polyimide substrate treated by inductively coupled oxygen plasma,” Surface and Coatings Technology, vol. 200, no. 7, pp. 2072-2079, 2005.
[64] S. H. Kim, S. H. Cho, N.-E. Lee, H. M. Kim, Y. W. Nam, and Y.-H. Kim, “Adhesion properties of cu/cr films on polyimide substrate treated by dielectric barrier discharge plasma,” Surface and Coatings Technology, vol. 193, no. 1, pp. 101-106, 2005, Asian-European International Conference on Plasma Surface Engineering 2003.
[65] K. W. Paik, H. S. Cole, R. J. Saia, and J. J. Chera, “Studies on metal/benzocyclobutene (bcb) interface and adhesion,” Journal of Adhesion Science and Technology, vol. 7, no. 5, pp. 403-415, 1993. eprint: https://doi.org/10.1163/156856193X00295. [66] S. Freilich and F. Ohuchi, “Reactions at the polyimide-metal interface,” Polymer, vol. 28, no. 11, pp. 1908-1914, 1987.
[67] F. S. Ohuchi and S. C. Freilich, “Metal polyimide interface: A titanium reaction mechanism,” Journal of Vacuum Science & Technology A, vol. 4, no. 3, pp. 1039-1045, 1986. eprint: https://doi.org/10.1116/1.573450.
[68] J. M. Burkstrand, “Metal-polymer interfaces: Adhesion and x-ray photoemission studies,” Journal of Applied Physics, vol. 52, no. 7, pp. 4795-4800, 1981. eprint: https://doi.org/10.1063/1.329320.
[69] K. L. Mittal, “Adhesion aspects of metallization of organic polymer surfaces,” Journal of Vacuum Science and Technology, vol. 13, no. 1, pp. 19-25, 1976. eprint: https://doi.org/10.1116/1.568850.
[70] Y. Nakamura, Y. Suzuki, and Y. Watanabe, “Effect of oxygen plasma etching on adhesion between polyimide films and metal,” Thin Solid Films, vol. 290-291, pp. 367-369, 1996, Papers presented at the 23rd International Conference on Metallurgical Coatings and Thin Films.
[71] S. B. Lee and Y.-K. Kim, “Adhesion improvement of polyimide/metal interface by he/o2/nf3 atmospheric pressure plasma,” Plasma Processes and Polymers, vol. 6, no. S1, S525-S529, 2009. eprint: https://onlinelibrary.wiley.com/doi/pdf/10.1002/ppap.200931111.
[72] T. P. Nguyen, A. Lahmar, and P. Jonnard, “Adhesion improvement of poly(phenylenevinylene) substrates induced by argon-oxygen plasma treatment,” The Journal of Adhesion, vol. 66, no. 1-4, pp. 303-317, 1998. eprint: https://doi.org/10.1080/00218469808009971.
[73] F. D. Egitto and L. J. Matienzo, “Plasma modification of polymer surfaces for adhesion improvement,” IBM Journal of Research and Development, vol. 38, no. 4, pp. 423-439, 1994.
[74] M. M. R. Howlader, T. Suga, A. Takahashi, K. Saijo, S. Ozawa, and K. Nanbu, “Surface activated bonding of lcp/cu for electronic packaging,” Journal of Materials Science, vol. 40, pp. 3177-3184, 2005.
[75] F. Faupel, V. Zaporojtchenko, A. Thran, T. Strunskus, and M. Kiene, “7-metal diffusion in polymers and on polymer surfaces,” in Diffusion Processes in Advanced Technological Materials, D. Gupta, Ed., Norwich, NY: William Andrew Publishing, 2005, pp. 333-363, ISBN: 978-0-8155-1501-2.
[76] F. Faupel, R. Willecke, and A. Thran, “Diffusion of metals in polymers,” Materials Science and Engineering: R: Reports, vol. 22, no. 1, pp. 1-55, 1998.
[77] J. H. Das and J. E. Morris, “Metal diffusion in polymers,” IEEE Transactions on Components, Packaging, and Manufacturing Technology: Part B, vol. 17, no. 4, pp. 620-625, 1994.
[78] H. Kudo, T. Takano, M. Tanaka, R. Kasai, J. Suyama, M. Akazawa, M. Takeda, H. Mawatari, T. Sasao, Y. Okazaki, et al., “A characterized redistribution layer architecture for advanced packaging technologies,” in 2016 IEEE 66th Electronic Components and Technology Conference (ECTC), IEEE, 2016, pp. 2063-2067.
[79] D. Okamoto, Y. Shibasaki, D. Shibata, T. Hanada, F. Liu, M. Kathaperumal, and R. R. Tummala, “Fabrication and reliability demonstration of 3 m diameter photo vias at 15 m pitch in thin photosensitive dielectric dry film for 2.5 d glass interposer applications,” in 2019 IEEE 69th Electronic Components and Technology Conference (ECTC), IEEE, 2019, pp. 2112-2116.
[80] C. Nair, B. DeProspo, H. Hichri, M. Arendt, F. Liu, V. Sundaram, and R. Tummala, “Reliability studies of excimer laser-ablated microvias below 5 micron diameter in dry film polymer dielectrics for next generation, panel-scale 2.5 d interposer rdl,” in 2018 IEEE 68th Electronic Components and Technology Conference (ECTC), IEEE, 2018, pp. 1005-1009.
[81] Y. Oka and N. Koizumi, “Effects of impurity ions on electrical properties of poly (vinylidene fluoride),” Polymer Journal, vol. 14, no. 11, pp. 869-876, 1982.
[82] M. Egginger and R. Schwoediauer, “Analysis of mobile ionic impurities in polyvinylalcohol thin films by thermal discharge current and dielectric impedance spectroscopy,” AIP Advances, vol. 2, no. 4, p. 042 152, 2012.
[83] E. Bumiller and C. Hillman, “A review of models for time-to-failure due to metallic migration mechanisms,” in White paper issued by DfR Solutions, 2009.
[84] D. Lambert, R. Gannamani, and R. Blish, “Dendrite fuse re-growth kinetics on organic substrates for microprocessors,” in 2004 IEEE International Reliability Physics Symposium. Proceedings, IEEE, 2004, pp. 543-546.
[85] S.-A. Kim, D.-S. Ahn, Y.-H. Eum, D.-H. Kim, and Y.-B. Kim, “Case study of copper dendrite growth under hast test,” in 2008 15th International Symposium on the Physical and Failure Analysis of Integrated Circuits, IEEE, 2008, pp. 1-3.
[86] D. S. Peck, “Comprehensive model for humidity testing correlation,” in 24th International Reliability Physics Symposium, IEEE, 1986, pp. 44-50.
[87] G. DiGiacomo, “Metal migration (ag, cu, pb) in encapsulated modules and timeto-fail model as a function of the environment and package properties,” in 20^{th} International Reliability Physics Symposium, IEEE, 1982, pp. 27-33.
[88] Polymer-Database. (2022). “Dielectric strength of polymers.” [89] C.-K. Hu, L. Gignac, E. Liniger, B. Herbst, D. Rath, S. Chen, S. Kaldor, A. Simon, and W.-T. Tseng, “Comparison of cu electromigration lifetime in cu interconnects coated with various caps,” Applied Physics Letters, vol. 83, no. 5, pp. 869-871, 2003.
[90] C.-K. Hu, D. Canaperi, S. Chen, L. Gignac, B. Herbst, S. Kaldor, M. Krishnan, E. Liniger, D. Rath, D. Restaino, et al., “Effects of overlayers on electromigration reliability improvement for cu/low k interconnects,” in 2004 IEEE International Reliability Physics Symposium. Proceedings, IEEE, 2004, pp. 222-228.
[91] H. Ono, T. Nakano, and T. Ohta, “Diffusion barrier effects of transition metals for cu/m/si multilayers (m=cr, ti, nb, mo, ta, w),” Applied Physics Letters, vol. 64, no. 12, pp. 1511-1513, 1994.
[92] T. Kanki, J. Ikeda, Y. Kobayashi, S. Suda, Y. Nakata, and T. Nakamura, “Development of highly reliable cu wiring of 1/s=1/1 m for chip to chip interconnection,” in 2012 IEEE International Interconnect Technology Conference, IEEE, 2012, pp. 1-3.
[93] Scs parylene properties, Specialty Coating Systems (SCS), 2016.
[94] A. Pizzagalli, “Lithography technology and trends for advanced packaging,” in 2016 China Semiconductor Technology International Conference (CSTIC), IEEE, 2016, pp. 1-3.
[95] M. Lapedus, Lithography challenges for fan-out.
[96] M. Griot, “Introduction to laser technology,” Technical Guide, pp. 10-6, 2009.
[97] B. Matuskova, B. Pova ̌zay, R. Holly, F. B\ddot{ }ugelsack, T. Zenger, T. Uhrmann, and B. Thallner, “Maskless lithography optimized for heterogeneous and chiplet integration,” in 2020 International Wafer Level Packaging Conference (IWLPC), IEEE, 2020, pp. 01-06.
[98] P. Nimbalkar, P. Bhaskar, C. Blancher, M. Kathaperumal, M. Swaminathan, and R. Tummala, “Novel zero side-etch process for; 1 m package redistribution layers,” in 2022 IEEE 72nd Electronic Components and Technology Conference (ECTC), IEEE, 2022, pp. 2168-2173.
[99] R. Iannuzzelli, “Predicting plated-through-hole reliability in high temperature manufacturing processes,” in 1991 Proceedings 41st Electronic Components & Technology Conference, IEEE, 1991, pp. 410-421.
[100] P. Nimbalkar, M. Kathaperumal, F. Liu, M. Swaminathan, and R. Tummala, “Reliability modeling of micro-vias in high-density redistribution layers,” in 2021 IEEE 71st Electronic Components and Technology Conference (ECTC), 2021, pp. 983-988.
[101] P. Nimbalkar, C. Blancher, M. Kathaperumal, M. Swaminathan, and R. Tummala, “Effect of titanium-polymer interactions on adhesion of polymer-copper redistribution layers in advanced packaging,” IEEE Transactions on Device and Materials Reliability, pp. 1-1, 2022.
[102] M. Du, R. Opila, and C. Case, “Interface formation between metals (cu, ti) and low dielectric constant organic polymer (flare™ 1.0),” Journal of Vacuum Science & Technology A: Vacuum, Surfaces, and Films, vol. 16, no. 1, pp. 155-162, 1998.
[103] Y. Nishimura, “Advanced insulating film for next-generation smartphone performance requirements,” Presented at ECTC, 2019. Pratik Nimbalkar et al. “Evaluation of Parylene-HT as Dielectric for Package Substrates”, 2023 IEEE 72nd Electronic Components and Technology Conference (ECTC). (Submitted)
[104] Prahalad Murali, Pratik Nimbalkar et al. “Maskless Lithography for High-Density Package Redistribution Layers”, 2023 IEEE 72nd Electronic Components and Technology Conference (ECTC). (submitted)
[105] Pratik Nimbalkar, R. Tummala, “A New Era in Packaging: Glass Panel to 1 m”, 2022 Pan Pacific Microelectronics Symposium.
[106] Pratik Nimbalkar et al. “Novel zero side-etch process for <1 m package redistribution layers”, 2022 IEEE 72nd Electronic Components and Technology Conference (ECTC).
[107] M. Kathaperumal, . . . Pratik Nimbalkar et al. “Two-/Multi-Photon Imaging for Characterization of Fine Line Features and Microvias in Advanced Packaging”, 2022 IEEE 72nd Electronic Components and Technology Conference (ECTC).
[108] Pratik Nimbalkar et al. “Reliability Modeling of Micro-vias in High-Density Redistribution Layers”, 2021 IEEE 71st Electronic Components and Technology Conference (ECTC).
[109] Pratik Nimbalkar et al. “Fabrication and reliability demonstration of 5 m redistribution layer using low-stress dielectric dry film”, 2020 IEEE 70th Electronic Components and Technology Conference (ECTC), pp. 62-67.
[110] F. Liu, . . . Pratik Nimbalkar et al. “Advances in High Performance RDL Technologies for Enabling IO Density of 500 IOs/mm/layer and 8-m IO Pitch Using Low-k Dielectrics”, 2020 IEEE 70th Electronic Components and Technology Conference (ECTC), pp. 1132-1139.
[111] R. Tummala, . . . Pratik Nimbalkar et al. “Glass Panel Packaging, as the Most LeadingEdge Packaging: Technologies and Applications,” 2020 Pan Pacific Microelectronics Symposium.
[112] R. Tummala, M. Swaminathan, Pratik Nimbalkar, A new and historic packaging era, Chip Scale Review, vol 26 (2) 2022, Report no. 6.

1. A method of fabricating a package substrate, the method comprising:
vaporizing a source material at a first temperature and a first pressure to form a vapor dimer of the source material;
heating the vapor dimer in an inert environment to a second temperature to form a vapor monomer at a second pressure, wherein the second temperature is higher than the first temperature, and wherein the second pressure is lower than the first pressure; and
introducing the vapor monomer to a chamber having a workpiece having an exposed surface to spontaneously deposit and polymerize the vapor monomer to form a layer of a polymer on at least the exposed surface of the workpiece

2. The method of claim 1, wherein the chamber has a spontaneous polymerization environment at a third temperature lower than the second temperature.

3. The method of claim 1, wherein the chamber has a spontaneous polymerization environment a third pressure lower than the second pressure.

4. The method of 1, wherein the spontaneous polymerization environment is at or near ambient temperature.

5. The method of claim 1, wherein the workpiece comprises a single layer or multi-layer glass, a second polymer, metal, silicon, semiconductor material, or a combination thereof.

6. The method of claim 1, wherein the workpiece comprises a glass substrate, organic laminate, silicon or metal or a second polymer substrate.

7. (canceled)

8. The method of claim 1, wherein the workpiece comprises a first exposed surface and a second exposed surface opposite to the first exposed surface, and wherein the vapor monomer is spontaneously deposited and polymerized simultaneously on both the first exposed surface and the second exposed surface to form a layer of the polymer on the first exposed surface and the second exposed surface, and
wherein a ratio of a thickness of polymer layer to a thickness of the workpiece is between 0.001 to 5.

9. The method of claim 1 further comprising:
introducing additional vapor monomer to the chamber to spontaneously deposit and polymerize the additional vapor monomer to form an additional layer or a mixture of the polymer on a portion of the workpiece.

10. The method of claim 1 further comprising:
successively introducing an additional vapor monomer to the chamber to spontaneously deposit and polymerize each additional vapor monomer to form successive additional layer of the polymer on successive layers of the workpiece.

11. The method of claim 1, wherein the substrate comprises a package substrate having a core substrate with multiple layers of copper and polymer dielectric.

12. The method of claim 1, wherein the workpiece comprises:
a package substrate having a core substrate with multiple layers of (i) patterned copper comprising two metal layers and (ii) the polymer, and wherein microvias/blind vias are formed in the polymer for vertical connection of the two metal layers, or
a package substrate, the polymer forming a build-up dielectric layer, solder-mask layer, thermal-interface material, underfill, or an overmold.

13. The method of claim 1, wherein the workpiece comprises one or more through-package-vias (TPVs) formed on a brittle substrate core.

14. (canceled)

15. (canceled)

16. The method of claim 1 further comprising:
depositing a thermally conductive material over the polymer, wherein the polymer provides a thin layer thermal interface having low thermal resistance to the thermally conductive material.

17. (canceled)

18. The method of claim 1, wherein the polymer comprises at least of: (i) poly-para-xylylene, Parylene-HT, Parylene-N, Parylene-C, Parylene-D, Parylene AF-4, Parylene-SF, Parylene-A, Parylene-AM, Parylene VT-4, Parylene-CF, and/or Parylene-X, or (ii) acrylic, epoxy, polyurethan, silicone, poly(tetrafluoroethylene), polyimide, fluoropolymer, or a combination thereof.

19. (canceled)

20. (canceled)

21. The method of claim 1, wherein the polymer is deposited conformally to fill one or more open areas of a cavity to create an overburden, wherein the overburden is removed by a subsequent planarization operation.

22. The method of claim 1, wherein the workpiece comprises:
a package substrate having a molded substrate with embedded chips, wherein the polymer is deposited on the molded substrate to form interconnections between multiple embedded/molded chips, or
a bridge substrate comprising a carrier with multiple layers of (i) metal and (ii) the polymer to form an interconnect, wherein the bridge substrate comprises a fused silica or glass carrier having a coefficient of thermal expansion from 0.1 ppm/K to 20 ppm/K.

23. (canceled)

24. (canceled)

25. (canceled)

26. (canceled)

27. The method of claim 1, wherein the workpiece comprises a package substrate comprising optical waveguides formed of the polymer, one or more filters, antennas, circulators, baluns, diplexers, power splitter & combiners, mixers, phase shifters, voltage-controlled oscillators, frequency multipliers and dividers, low noise amplifiers, power amplifiers, inductors, capacitors, co-planar waveguides, microstrip, waveguides, or combination thereof.

28. A method of claim 1, wherein the workpiece comprises a package substrate comprising the polymer conformally deposited onto one or more RF components, the method further comprising:
depositing a layer of conductive material for electromagnetic interference shielding.

29. An apparatus comprising:
a package substrate comprising a core substrate configured with multiple layers of metal and polymer dielectric, wherein at least one polymer layers of the polymer dielectric is deposited by spontaneous polymerization of a vapor monomer.

30. The apparatus of claim 29, wherein the multiple layers of metal and polymer dielectric include microvias or blind vias for vertical connection of at least two metal layers.

31. The apparatus of claim 29, wherein the package substrate includes through-package-vias (TPVs), wherein the TPVs are conformally coated with the polymer dielectric by spontaneous polymerization, thereby filling defects, voids, and cracks in the core substrate.

32. The apparatus of claim 29,
wherein the multiple layers of metal are formed by metal deposition through electroless or sputtering followed after conformal dielectric coating via spontaneous polymerization, or
wherein the multiple layers of metal and polymer dielectric comprises a build-up dielectric layer, a solder-mask layer, a thermal-interface material, an underfill. an overmold, or a combination formed by the spontaneous polymerization of the vapor monomer.

33. (canceled)

34. The apparatus of claim 29, wherein the polymer dielectric is conformally deposited onto the packaged substrate followed by a deposition of a thermally conductive material.

35. The apparatus of claim 29, wherein a layer of polymer dielectric acts as a thermal interface material providing low thermal resistance.

36. The apparatus of claim 29, wherein the package substrate is manufactured using a dual damascene, a semi-additive, or an embedded trench process.

37. The apparatus of claim 29, wherein the polymer dielectric, as deposited, comprises poly-para-xylylenes, acrylic, epoxy, polyurethane, silicone, poly(tetrafluoroethylene), polyimides, fluoropolymers, or a combination thereof.

38. (canceled)

39. The apparatus of claim 29, wherein the package substrate comprises a layer of high-density capacitors, wherein the capacitor is formed of two metal electrodes with a layer of the polymer dielectric formed therebetween, the polymer dielectric having a dielectric constant less than 3.

40. (canceled)

41. The apparatus of claim 29,
wherein the package substrate comprises a cavity for embedded chips/chiplets, devices, components, passive components, active components, or a combination thereof, and wherein polymer dielectric is deposited conformally to (i) fill open areas of the cavity and (ii) create an overburden followed by planarization to remove the overburden, or
wherein the package substrate is a molded substrate with embedded chips for fan-out or embedded wafer bonding, and wherein the polymer dielectric is deposited on the molded substrate to form interconnections between multiple embedded/molded chips, chiplets, devices, components, passive components, active components, or a combination thereof.

42. (canceled)

43. An embedded bridge substrate comprising a carrier made of thin glass, silicon, metal, or inorganic material, the carrier formed of multiple layers of metal and polymer dielectric for forming interconnections between chips/chiplets, devices, components, passive components, active components, or a combination thereof, wherein polymer layers of the polymer dielectric are deposited by spontaneous polymerization of a vapor monomer.

44-49. (canceled)
